(19) United States
(12) Patent Application Publication
(10) Pub. No.: US 2026/0162721 A1
(43) Pub. Date: Jun. 11, 2026

(54) SPATIALLY CONTROLLED DATA TRANSFER

(71) Applicant: Atlas Data Storage, Inc., South San Francisco, CA (US)

(72) Inventors: Jeremy LACKEY, Foster City, CA (US); William BANYAI, South San Francisco, CA (US)

(21) Appl. No.: 19/449,814

(22) Filed: Jan. 15, 2026

Related U.S. Application Data
(63) Continuation of application No. PCT/US2024/038379, filed on Jul. 17, 2024.
(60) Provisional application No. 63/514,230, filed on Jul. 18, 2023.

(51) Int. Cl. G11C 13/02

(52) U.S. Cl. CPC G11C 13/02

(57) ABSTRACT

Described herein are devices, systems, methods for transferring information encoded by and stored in polynucleotide molecules. The information can be transferred by contacting the plurality of biomolecules residing on a first surface with another second surface, conjugating the biomolecules to the second surface, and cleaving the biomolecules from the first surface.

### CROSS-REFERENCE TO RELATED APPLICATIONS

This application claims priority to U.S. Provisional Application No. 63/514,230, filed on Jul. 18, 2023, which is hereby incorporated by reference in its entirety. All publications, patents, and patent applications mentioned in this specification are herein incorporated by reference to the same extent as if each individual publication, patent, or patent application was specifically and individually indicated to be incorporated by reference.

### BACKGROUND

Organic polynucleotide molecules capable of storing information, such deoxyribonucleic acid (DNA), possess a number of advantages over existing electronic media used for information storage. Examples of such advantages include superior density, stability, energy-efficiency, and longevity. However, existing attempts at storing information in DNA have been hampered by technical challenges such as effective coding and random access. There is a need to develop superior methods to efficiently store and access DNA.

### SUMMARY

Provided herein is a method for transferring information comprising: storing the information in a plurality of biomolecules, wherein the plurality of biomolecules reside at one or more first loci of a first surface; providing a second surface comprising one or more second loci, wherein the one or more second loci comprise one or more droplets; contacting the plurality of biomolecuels residing on at least one locus of the first surface with at least one droplet of the second surface; and transferring the plurality of biomolecules at the at least one locus of the first surface to the at least one droplet of the second surface. Contacting the plurality of biomolecules residing on at least one locus of the first surface with at least one droplet of the second surface may comprise aligning the first surface with the second surface. Transferring the plurality of biomolecules at the at least one locus of the first surface to the at least one droplet of the second surface may comprise preserving spatial arrangement or information thereof of the plurality of biomolecules. In addition or alternatively, transferring the plurality of biomolecules at the at least one locus of the first surface to the at least one droplet of the second surface may comprise conjugating the plurality of biomolecules to the second surface, and/or cleaving the plurality of biomolecules from the first surface. The one or more first loci, the one or more second loci, or both, may comprise an inner region comprising a first functionalization agent, and an outer region comprising a second functionalization agent. The inner region may comprise a hydrophilic region and/or the outer region may comprise a hydrophobic region. The one or more first loci, the one or more second loci, or both, may comprise a pitch distance of about 0.1 μm to about 10 μm. The one or more droploets on the second surface may be formed by cooling the second surface in a humid environment. The method may include prior to contacting the plurality of biomolecules residing on at least one locus of the first surface with at least one droplet of the second surface, functionalizing the inner region of the second surface, the plurality of biomolecules, or both. The inner region of the second surface, the plurality of biomolecules, or both, may be functionalized with a clickable moiety. In addition or alternatively, the inner region of the second surface or the plurality of biomolecules are functionalized with a thiol, an imidazole, an amine, an alkyne, a diene, or a biotin.

Also provided herein is a system for transferring information comprising at least one processing unit; a memory unit communication with the at least one processing unit; an organic storage unit in communication with the at least one processing unit; an organic storage unit in communication with the at least one processing unit and the memory unit; and instructions stored in the memory unit and executed on the at least one processing unit that cause the system to transfer information in the organic storage unit through one or more operations. The organic storage unit may comprise at least one active surface comprising a plurality of biomolecules encoding information, wherein the plurality of biomolecules reside on one or more first loci; and/or at least one inactive surface comprising one or more droplets, wherein the one or more droplets reside on one or more second loci. The one or more operations may comprise contacting the plurality of biomolecules at least one locus of the at least one active surface with at least one droplet of the at least one inactive surface; and/or transferring the plurality of biomolecules at the at least one locus to the at least one droplet of the at least one inactive surface. The system may further comprise a deposition chamber where the deposition chamber deposits the one or more droplets on the at least on inactive surface. The system may further comprise a synthesizer unit, where the synthesizer unit generates the plurality of biomolecules on the at least one active surface. The system may further comprise a robotic system configured to align the at least one active surface with the at least one inactive surface. Transferring the plurality of biomolecules at the at least one locus of the first surface to the at least one droplet of the second surface may comprise preserving spatial arrangement or information thereof of the plurality of biomolecules. In addition or alternatively, transferring the plurality of biomolecules at the at least one locus of the first surface to the at least one droplet of the second surface may comprise conjugating the plurality of biomolecules to the second surface, and/or cleaving the plurality of biomolecules from the first surface. The one or more first loci, the one or more second loci, or both, may be addressable by electrode. The one or more first loci, the one or more second loci, or both, may comprise an inner region comprising a first functionalization agent, and an outer region comprising a second functionalization agent. The inner region may comprise a hydrophilic region and/or the outer region may comprise a hydrophobic region. The one or more first loci, the one or more second loci, or both, may comprise a pitch distance of about 0.1 μm to about 10 μm.

### BRIEF DESCRIPTION OF THE DRAWINGS

A better understanding of the features and advantages of the present subject matter will be obtained by reference to the following detailed description that sets forth illustrative embodiments and the accompanying drawings of which:

FIG. 1A is an illustration depicting droplet deposition on a surface in an exemplary process of differential functionalization on the surface, according to aspects of the present disclosure.

FIG. 1B is an illustration depicting transferring molecules from one surface to another surface in an exemplary process of differential functionalization on the surface, according to aspects of the present disclosure.

FIG. 2 depicts an exemplary conjugation scheme for transferring molecules from one surface to another, according to aspects of the present disclosure.

FIG. 3 is a diagram depicting an exemplary system for synthesizing, storing, and sequencing a plurality of polynucleotides, according to aspects of the present disclosure.

FIG. 4 is a diagram depicting an exemplary computing device with memory, storage, one or more processors, and a network interface, according to aspects of the present disclosure.

### DETAILED DESCRIPTION

High density spatial addressability on a chip, such as a complementary metal-oxide semiconductor (CMOS) chip, can have many applications in drug discovery, synthetic biology, DNA data storage, pharmaceuticals as well as other areas of interest. However, the cost of generating, let alone storing such as massively parallel array on a CMOS chip may be relatively high. In such instances, it can be advantageous to precisely transfer the array from a synthesis chip or a CMOS chip to a cheaper substrate (e.g., glass) while maintaining spatial addressability. In such instances, the desired assay can be performed on the cheaper substrate, such as a glass substrate, or the polynucleotides may be stored on the cheaper substrate in DNA data storage. Further, the synthesis chip or the CMOS chip can be reused, thus lowering overall cost.

Provided herein are methods of transferring information. The method can comprise one or more of: (a) storing the information in a plurality of biomolecules, wherein the plurality of molecules reside at one or more loci of a first surface; (b) providing a second surface comprising one or more droplets; (c) contacting the plurality of biomolecules residing on at least one locus of the first surface with at least one droplet of the second surface; and (d) transferring the plurality of biomolecules at the at least one locus of the first substrate to the at least one droplet of the second surface.

Also provided herein is systems for transferring information. The system can comprise one or more of: at least one processing unit; a memory in communication with the at least one processing unit; an organic storage in communication with the at least one processing unit and the memory; and instructions stored in the memory and executed on the one or more processing units that cause the system to transfer the information in the organic storage through one or more operations. In some instances, the organic storage comprises one or more of: at least one active surface comprising a plurality of molecules encoding information, wherein the plurality of molecules reside on one or more loci; and at least one inactive surface comprising one or more droplets. In some instances, the one or more operations can comprise: contacting at least one locus of the at least one active surface with at least one droplet of the at least one inactive surface, transferring the plurality of biomolecules at the at least one locus to the at least one droplet of the at least one inactive surface, or both.

### Definitions

Unless otherwise defined, all technical terms used herein have the same meaning as commonly understood by one of ordinary skill in the art to which the present subject matter belongs.

Throughout this disclosure, numerical features are presented in a range format. It should be understood that the description in range format is merely for convenience and brevity and should not be construed as an inflexible limitation on the scope of any embodiments. Accordingly, the description of a range should be considered to have specifically disclosed all the possible subranges as well as individual numerical values within that range to the tenth of the unit of the lower limit unless the context clearly dictates otherwise. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual values within that range, for example, 1.1, 2, 2.3, 5, and 5.9. This applies regardless of the breadth of the range. The upper and lower limits of these intervening ranges may independently be included in the smaller ranges, and are also encompassed within the invention, subject to any specifically excluded limit in the stated range. Where the stated range includes one or both of the limits, ranges excluding either or both of those included limits are also included in the invention, unless the context clearly dictates otherwise.

The terminology used herein is for the purpose of describing particular embodiments only and is not intended to be limiting of any embodiment. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Reference throughout this specification to “some instances,” “further instances,” or “a particular instance,” means that a particular feature, structure, or characteristic described in connection with the instance is included in at least one instance. Thus, the appearances of the phrase “in some instances,” or “in further instances,” or “in a particular instance” in various places throughout this specification are not necessarily all referring to the same instance. Furthermore, the particular features, structures, or characteristics may be combined in any suitable manner in one or more instances.

Unless specifically stated or obvious from context, as used herein, the term “about” in reference to a number or range of numbers is understood to mean the stated number and numbers +/−10% thereof, or 10% below the lower listed limit and 10% above the higher listed limit for the values listed for a range.

Polynucleotide sequences described herein may be, unless stated otherwise, comprise DNA or RNA or an analog or derivative thereof. In some instances, nucleic acids are connected via phosphate or sulfur-containing linkages. Nucleic acids in some instances comprise DNA, RNA, non-canonical nucleic acids, unnatural nucleic acids, or other nucleoside. In some instances, nucleotides comprise non-canonical bases, sugars, or other moiety. In some instances, nucleotides comprise terminators which are configured to prevent extension reactions. In some instances, such terminators may be removed before addition of subsequent nucleotides to the growing chain.

### Data Transfer and Storage

Provided herein are systems and methods for transferring information in organic form. The systems and method provided herein may be used to transfer information while maintaining spatial addressability. Maintaining spatial addressability can allow for efficient tracking of information for subsequent downstream applications, such as storage, retrieval or access. The information may be stored in organic form by encoding the information in molecules. The molecules may comprise biomolecules, such as polynucleotides or polypeptides. The molecules encoding information may reside on a surface of a substrate, and may be transferred to another surface using systems and methods described herein. Systems and methods described herein for transferring biomolecules from one surface to another may be used to “copy” information from one location to another location with spatial control. In some instances, information storage using a plurality of polynucleotides may be used in place of or in conjunction with in silico memory, as further described herein.

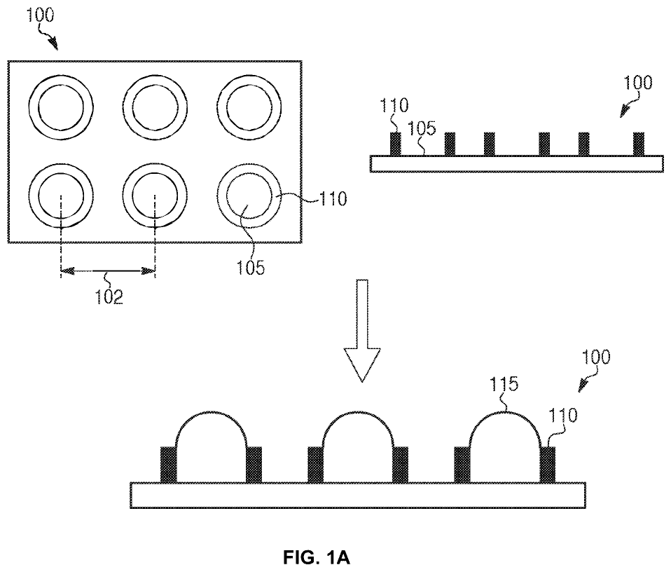

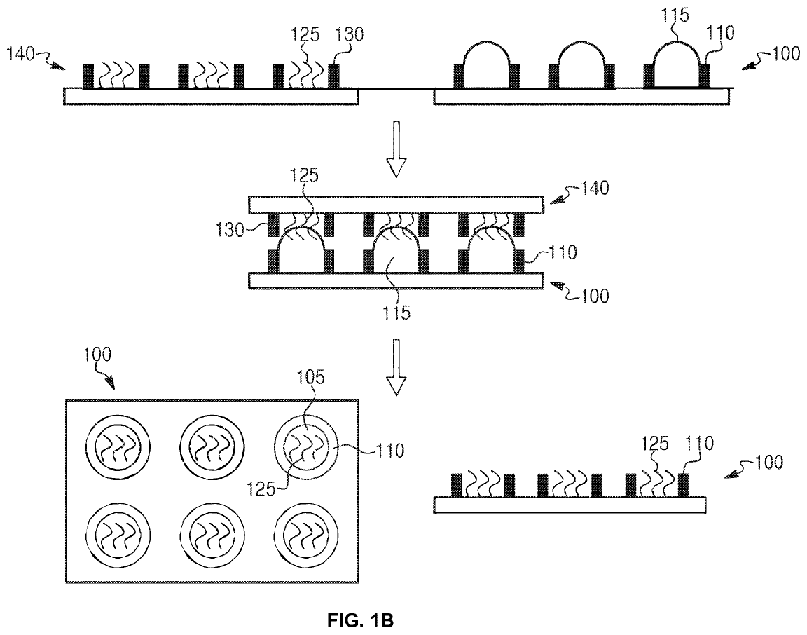

An exemplary scheme for transferring biomolecules is provided in FIG. 1A and FIG. 1B. FIG. 1A illustrates a top view and a side view of a surface 100 of a substrate. In some instances, the surface comprises glass. The surface 100 may be patterned. In some instances, the surface is patterned by differentially functionalization of the surface, structural features, or both. In some examples, the surface is patterned with structures, such as recesses or protrusions forming features or grids, such as loci (e.g., wells or cells) on the surface. In some examples, the surface is patterned by differential functionalization to form features or grids (e.g., chemical functionalization such as hydrophobic or hydrophilic features), which may form loci (e.g., wells or cells) on the surface. As shown in FIG. 1A, the surface 100 may be patterned to form one or more wells. While FIG. 1A illustrates an example of a surface with six features, one of skill in the art will appreciate that the number of features (e.g., wells) may be adjusted, (e.g., one, ten, fifty, one hundred, five hundred, one thousand, ten thousand, twenty thousand, fifty thousand, hundred thousand, or millions of features).

As shown in FIG. 1A, the surface may comprise features (e.g., loci) with barriers 110. The barriers 110 may comprise a first functionalization, a structural barrier, or both. In some examples the barriers 110 only comprise a functionalization (e.g., no structural barrier). In some example the barriers 110 comprise the outer perimeter of each feature or loci on the surface 100. Each feature or loci may comprise an inner region 105. In some examples, the inner region 105 may be surrounded by the barrier 110 on all sides. The inner region 105 may comprise a second functionalization, a structural barrier, or both. In some examples, the inner region 105 only comprise a functionalization (e.g., no structural barrier). In some examples, the first functionalization of the barriers 110 and the second functionalization of the inner regions 105 are different. In some instances, each of the inner regions 105 on each of the features or loci are the same. In some instances, each of the inner regions 105 on each of the features or loci are not the same. Referring to FIG. 1A, in some instances, the barriers 110 are functionalized such that the barriers 110 comprise hydrophobic regions, while the inner regions 105 are functionalized such that they comprise hydrophilic regions.

Each feature or loci (e.g., including the barriers and inner region) on the surface may have a pitch distance 102. The pitch distance 102 may be about 0.1 μm to about 10 μm. In some instances, the pitch distance 102 is about 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.2, 2.5, 2.8, 3, 3.5, 4, 4.5, 5, 6, 7, 8, 9, or 10 μm. In some instances, the pitch distance 102 is at least about 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.2, 2.5, 2.8, 3, 3.5, 4, 4.5, 5, 6, 7, 8, 9, or 10 μm. In some instances, the pitch distance 102 is at most about 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.2, 2.5, 2.8, 3, 3.5, 4, 4.5, 5, 6, 7, 8, 9, or 10 μm. In some instances, the pitch distance 102 is about 0.1 to 0.5, 0.1 to 0.8, 0.1 to 1, 0.1 to 1.2, 0.1 to 1.5, 0.1 to 2, 0.1 to 3, 0.5 to 0.8, 0.5 to 1, 0.5 to 1.2, 0.5 to 1.5, 0.5 to 2, 0.8 to 1, 0.8 to 1.2, 0.8 to 1.5, 0.8 to 2, 1 to 1.2, 1 to 1.5, 1 to 2, 1 to 3, 1 to 4, 1 to 5, 1 to 8, 1 to 10, 1.2 to 1.5, 1.2 to 1.8, 1.2 to 2, 1.5 to 1.8, 1.5 to 2, 1.5 to 2.5, 1.5 to 3, 2 to 5, 2 to 8, 2 to 10, 3 to 5, 3 to 8, 3 to 10, 5 to 8, 5 to 10, or 8 to 10 μm.

In some instances, droplets 115 may be deposited onto or formed on features on the surface. In some instances, the substrate may be placed in a humid environment, and water droplets may be formed and be contained inside the patterned features (e.g., inner region 105). The droplets may reside within the inner region 105 of the features or loci on the surface 100. The droplets 115 may be confined by the barrier 110 of the loci. In some instances, droplets are deposited onto some or all features on a surface. In some instances, droplets are deposited on to some or all of the features on a surface with deposition chamber. In some examples, the deposition chamber comprises a deposition unit for depositing droplets on some or all of the features on a surface. In some examples, the deposition chamber comprises a humid environment that is exposed to some or all of the features to deposit droplets on the some or all of the features. In some instances, droplets are formed on about 1%, 5%, 10%, 15%, 20%, 25%, 30%, 40%, 50%, 60%, 70%, 80%, 90%, or 100% of the features on the surface. Referring to FIG. 1A, a surface 100 may be referred to as an inactive surface (e.g., without comprising molecules). The droplets 115 may comprise one or more reagents that can be used to transfer molecules to the current surface as described herein.

Transferring molecules can comprise providing a surface with a plurality of molecules. The plurality of molecule may encode information as described herein, thereby transferring the information from one surface to another. Referring to FIG. 1B, the surface 140 comprising molecules 125 may similarly have one or more features or loci as illustrated for the surface 100. The surface 140 may be the surface of a substrate for generating or synthesizing the molecules, such as for example those described herein. In some instances, the surface 140 is a surface of a CMOS chip. In some instances, the molecules 125 may be confined by the barrier 130 of a feature or loci on the surface 140. In some instances, the molecules 125 reside on the inner region of some or all of the feature or loci on the surface 140. In some instances, the molecules 125 are tethered to the inner region of each feature or loci on the surface 140. In some instances, the plurality of molecules 125 are tethered to the inner region of each feature or loci on the surface 140. The plurality of molecules 125 may be tethered to the surface via a linkage. In some instances, the linkage is a cleavable moiety. For example, the surface 140 may be functionalized to provide cleavable linkers for covalent attachment to the oligonucleotides. The linker moiety may be six, eight, ten, or more atoms in length. Alternatively, the cleavable moiety may be within an oligonucleotide and may be introduced during in situ synthesis of biomolecules on the surface, such as polynucleotide synthesis. A broad variety of cleavable moieties are available in the art of solid phase and microarray oligonucleotide synthesis (see, e.g., Pon, R., Methods Mol. Biol., 1993, 20:465-496; Verma et al., Annu. Rev. Biochem., 1998, 67:99-134; U.S. Pat. No. 5,739,386; U.S. Pat. No. 5,700,642; U.S. Pat. No. 5,830,655; U.S. Publication No. 2003/0186226; and U.S. Publication No. 2004/0106728, which are incorporated herein by reference in their entirety). The cleavable moiety may be removed under conditions which do not degrade the oligonucleotides. In some instances, the droplets 115 provide conditions for cleaving the linkage between the molecules 125 and the surface 140.

Transferring molecules can comprise contacting a first surface and a second surface. The first surface can comprise a plurality of molecules, such as biomolecules (e.g., polynucleotides or polypeptides), and the second surface can comprise a plurality of droplets as illustrated, for example, in FIG. 1B. In some instances, transferring comprises contacting the plurality of molecules 125 on the first surface 140 with the plurality of droplets 115 on the second surface 100. The plurality of droplets can provide conditions for cleaving the linkage between the molecules 125 to the first surface 140. In some instances, the plurality of droplets comprise one or more reagents for cleaving the linkage between the molecules 125 to the first surface 140. Methods and compositions for cleaving molecules (e.g., polynucleotides) from a surface of a solid support may comprise, but are not limited to, those described further herein.

In some instances, transferring comprises aligning at least one surface comprising molecules (referred to as “active surface”) with the at least one surface without molecules (referred to as “inactive surface”). In some instances, the surfaces may be aligned using a robotic system. In some instances, transferring comprises contacting the plurality of molecules residing on at least one locus of the first surface with at least one droplet of the second surface. In some instances, transferring comprises attaching the plurality of biomolecules to the second surface 100. In some instances, attaching the plurality of biomolecules to the second surface comprises conjugating the plurality of biomolecules to the second surface 100. In some instances, attaching the plurality of biomolecules to the second surface comprises cleaving the plurality of biomolecules from the first surface 140. In some instances, the plurality of polynucleotides are cleaved from a surface 140 before they are attached to another surface 100. In some instances, the plurality of polynucleotides are cleaved from a surface 140 after they are attached to another surface 100. In some instances, one or more surfaces involved in the transfer comprise a mechanism for alignment. In some instances, the mechanism comprises fudicual markings, protrusions/recesses, magnetic or electrical connections, or other mechanism for aligning the surfaces prior to transfer.

In some instances, the number, dimensions, or both of the loci on the two surfaces (e.g., surface 100 and surface 140 in FIG. 1B) are the same. In some instances, the number of loci on the two surfaces are different but the dimensions are the same. In such instances, some or all of the molecules on the surface 140 are transferred from one surface to another. In some examples, about 1%, 5%, 10%, 15%, 20%, 25%, 30%, 40%, 50%, 60%, 70%, 75%, 80%, 85%, 90%, 95%, or 100% of the molecules on an active surface (e.g., 140) are transferred to the inactive surface (e.g., 100). In some examples, at least about 1%, 5%, 10%, 15%, 20%, 25%, 30%, 40%, 50%, 60%, 70%, 75%, 80%, 85%, 90%, or 95% of the molecules on an active surface (e.g., 140) are transferred to the inactive surface (e.g., 100). In some examples, at most about 5%, 10%, 15%, 20%, 25%, 30%, 40%, 50%, 60%, 70%, 75%, 80%, 85%, 90%, 95%, or 100% of the molecules on an active surface (e.g., 140) are transferred to the inactive surface (e.g., 100). In some examples, about 1-5%, 1-10%, 1-15%, 1-20%, 1-50%, 1-100%, 5-10%, 5-20%, 5-30%, 5-50%, 5-100%, 10-15%, 10-20%, 10-25%, 10-30%, 10-40%, 10-50%, 10-80%, 10-100%, 20-40%, 20-50%, 20-80%, 20-100%, 30-50%, 30-60%, 30-80%, 30-100%, 40-50%, 40-60%%, 40-80%, 40-100%, 50-60%, 50-70%, 50-80%, 50-90%, 50-100%, 60-80%, 60-100%, 70-80%, 70-90%, 70-100%, 80-90%, 80-100%, or 90-100% of the molecules on an active surface (e.g., 140) are transferred to the inactive surface (e.g., 100). In some examples, molecules from about 1%, 5%, 10%, 15%, 20%, 25%, 30%, 40%, 50%, 60%, 70%, 80%, 90%, or 100% of loci on an active surface (e.g., 140) are transferred to the inactive surface (e.g., 100). In some examples, molecules from at least about 1%, 5%, 10%, 15%, 20%, 25%, 30%, 40%, 50%, 60%, 70%, 75%, 80%, 85%, 90%, or 95% of loci on an active surface (e.g., 140) are transferred to the inactive surface (e.g., 100). In some examples, molecules from at most about 5%, 10%, 15%, 20%, 25%, 30%, 40%, 50%, 60%, 70%, 75%, 80%, 85%, 90%, 95%, or 100% of loci on an active surface (e.g., 140) are transferred to the inactive surface (e.g., 100). In some examples, molecules from at most about 1-5%, 1-10%, 1-15%, 1-20%, 1-50%, 1-100%, 5-10%, 5-20%, 5-30%, 5-50%, 5-100%, 10-15%, 10-20%, 10-25%, 10-30%, 10-40%, 10-50%, 10-80%, 10-100%, 20-40%, 20-50%, 20-80%, 20-100%, 30-50%, 30-60%, 30-80%, 30-100%, 40-50%, 40-60%%, 40-80%, 40-100%, 50-60%, 50-70%, 50-80%, 50-90%, 50-100%, 60-80%, 60-100%, 70-80%, 70-90%, 70-100%, 80-90%, 80-100%, or 90-100% of loci on an active surface (e.g., 140) are transferred to the inactive surface (e.g., 100). The spatial arrangement and addressability of the molecules may be maintained subsequent to the transfer to a new surface.

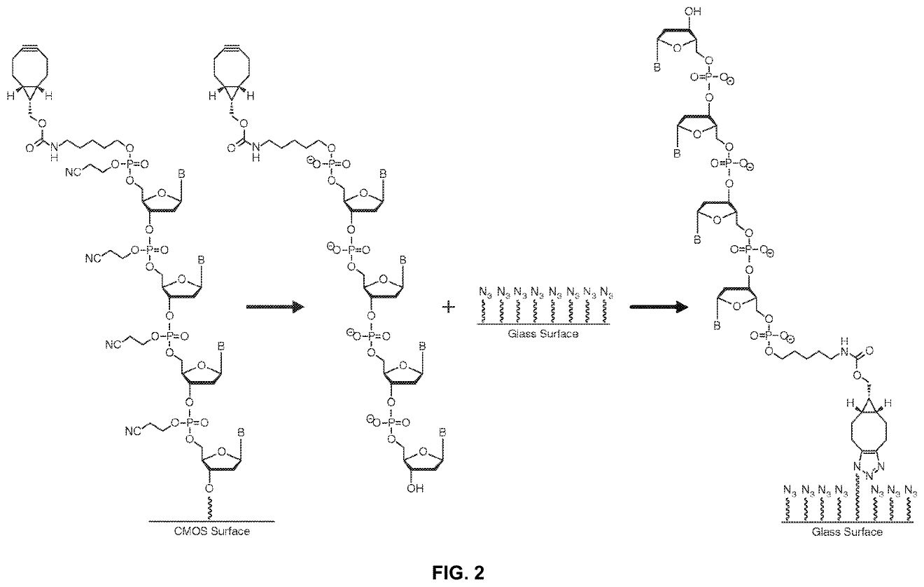

An exemplary schematic for transferring biomolecules is provided in FIG. 2. The biomolecules can comprise polynucleotides. The biomolecules, such as polynucleotides, may be tethered to the surface of a solid support. In some instances, the polynucleotides are tethered to a surface of a complementary metal-oxide semiconductor (CMOS) chip. In some instances, various layers of one or more devices are connected laterally via routing, and/or vertically with vias. In some instances, various layers of one or more devices are connected laterally via routing, and/or vertically with vias to a CMOS layer. In some instances, various layers of one or more devices are connected to a CMOS device via wire bonds, pogo pin contacts, or through Si Vias (TSV). In some instances, arrays of devices are independently addressable. In some instances, layers or components of devices comprising conducting materials function as cathodes or anodes when a voltage is applied. In some instances, the plurality of loci on the surface are addressable. In some instances, the plurality of loci on the surface are addressable by electrodes.

The biomolecules tethered to a surface may have a moiety that can form a linkage with a different surface. The moiety may be a terminal moiety, as illustrated for example in FIG. 2. The moieties on a surface (e.g., the inner region 105 of a surface as illustrated in FIGS. 1A-1B) and a terminal moiety of a biomolecule may be conjugated. In some instances, the linkage is reversible. In some instances, the linkage is not reversible. In some instances, the inner region of a surface, the plurality of biomolecules, or both are functionalized. In some examples, the inner region of a surface, the plurality of biomolecules, or both are functionalized with a clickable moiety. In some examples, functionalizing comprises functionalizing with a clickable moiety. In some instances, conjugating the plurality of biomolecules to a surface comprises conjugating using click chemistry. In some examples, the click chemistry comprises an azide-alkyne click conjugation, as illustrated in FIG. 2. In some examples, a first moiety for conjugation comprises a thiol, an imidazole, an amine, an alkyne, a diene, a biotin, and a second moiety comprises a maleimide, a haloacetamide, an aldehyde, an isothiocyanate, an isocyanate, a vinyl sulphone, an azide, or a tetrazine, or a streptavidin. The first moiety may be on the polynucleotide and the second moiety may be on the surface, or vice versa.

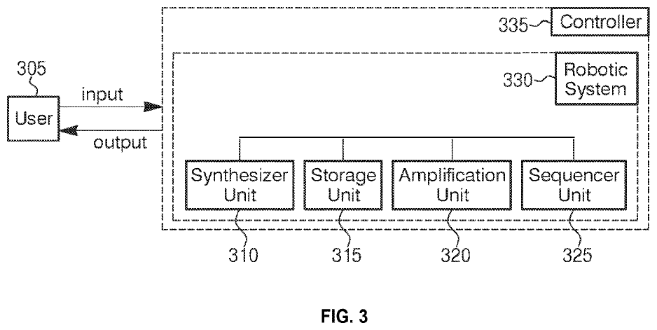

The methods for transferring information as described herein may be part of a system for transferring information. A system for transferring information can comprise a data storage system. The data storage system can comprise one or more components as generally illustrated in FIG. 3. A system for data storage or transfer can comprise one or more modules. In some instances, the some or all of the one or more modules are in communication. In some examples, some or all of the one or more modules are in communication to allow transferring of polynucleotides between them. In some examples, some or all of the one or more modules are fluidically coupled. In some examples, some or all of the one or more modules are fluidically coupled with one or more tubes. A fluid may generally refer to one or more liquids used in various processes involved in handling polynucleotides, including, without limitation, synthesis, amplification, preparation for sequencing, and sequencing. In some examples, some or all of the modules are in communication to allow transferring of control commands between modules of the system. In some examples, some or all of the one or more modules are electronically coupled. A module in the system can comprise, without limitation, a synthesizer unit, an amplification chamber, a sequencer unit, a storage unit, a controller, a robotic system, or any combination thereof. In some examples, a module can further comprise a fluid source, a database, or a file system, or both. In some examples, the database or file system keeps track of the storage capacity of the system. For example, the database or file system can keep track of available racks (or trays), slots (for capsules), or both. In some examples, the database or the file system is used to determine the disposition of the rack within the storage system. In some instances, movement of polynucleotides between one or more modules of a system is accomplished by one or more tubes or a robotic system. In some examples, the database or the file system is used to direct the robotic system to the correct position in the storage system. In some instances, the system is autonomous.

A data storage system or transfer may be a control system. A control system may generally refer to a framework to coordinate operations between protocols, connections, modules, and devices, so they may be executed properly and on schedule. In some embodiments, the operations may be executed with one or more logic elements comprising a programmable logic controller (PLC), programable logic array (PLA), programmable array logic (PAL), generic logic array (GLA), complex programmable logic decide (CPLD), field programable gate array (FPGA), or application-specific integrated circuit (ASIC). The control system may comprise one or more network communication protocols that may be standard network communication protocols, non-standard network communication protocols, or any combination thereof. In some embodiments, the standard network communication protocols are process field bus (Profibus), process field net (Profinet), highway addressable remote transducer (HART), distributed network protocol (DNP3), Modbus, open platform communication (OPC), building automation and control networks (BACnet), common industrial protocol (CIP), or ethernet for control automation technology (EtherCAT). A data storage system may include industrial, manufacturing, or processing facilities. Such facilities may support objectives on a mass-scale, such as synthesizing, storing, or retrieving information stored in biomolecules. A data storage system may comprise one or more of PLCs, remote terminal units, intelligent electronic devices, engineering workstations, human machine interfaces (HMIs), data historians, communication gateways, and front-end processors. In some embodiments, a data storage system may have different controllable states as steps of a process. In some embodiments, a data storage or transfer system may use an open communication protocol.

A non-limiting example of a system for data storage is illustrated in FIG. 3, with a feedback loop. A feedback loop may generally comprise a user 305 that can interact with a system via a controller 335 (e.g., PLC), for example, through a human-machine interface (HMI). The HMI may be a user interface (e.g., GUI) that connects a person or a user to one or more components (e.g., equipment, network, etc.) in the system. In some instances, a user may send an input, for example, as a query, to the controller 335, regarding the state or function of components of the system. In some instances, the query is related to an item of information, whole or in part, that is stored in the system, such as the location, duration, or metadata of the information stored in the system.

The controller 335 may send an output to a user 305. The output can comprise a response to the query, which can be provided through an HMI and may be displayed on the user interface. In some instances, the controller 335 sends status information regarding components of the ICS to the HMI and it is provided to the user 305. In some instances, the controller 335 implements control strategies using a system comprising a microprocessor for managing components in the system.

In some cases, the components may be a physical device, such as equipment in the system. The physical devices can be a device employed for storage or retrieval information in biomolecules. For example, physical devices can be part of a synthesizer unit 310, storage unit 315, amplification unit 320, or sequencer unit 325. In some examples, physical devices comprise one or more solid supports, for example, solid supports for transfer of biomolecules as illustrated herein (e.g., FIGS. 1A-1B). In some examples, physical devices can comprise a robotic system 330, which can be used for transferring or handling biomolecules or substrates in the system. In some cases, the equipment may be on-site or remote. In some examples, the controller 335 control a physical device or a plurality thereof, such as control motors, valves, switches, etc., in the system.

A controller 335 may controls a physical device based on one or more measurements obtained from sensors in the system. In some instances, sensors are integrated into one or more modules (e.g., a synthesizer unit 310, storage unit 315, amplification unit 320, or sequencer unit 325, robotic system 335, flow cell assembly, or biomolecule processing systems, etc.). In some instances, sensors determine when and how the physical device should operate. For example, the sensor may be an integrated sensor as part of a control device comprising an actuator. In some cases, the measurements may be physical measurements obtained from sensors, such as pressure, volume, temperature, humidity, torque, vacuum, motion, flow rate (e.g., fill rate or evacuation rate), angles of orientation of devices (e.g., flow cells), etc. In some cases, the sensor is a standalone sensor. In further instances, the controller 335 receives commands for the physical device to perform functions (e.g., pump actuation, stirrer operation, conveyor belt operation, etc.) from a user 305, for example through an HMI.

The data from operations or sensors in the system, as described herein, may be fed into one or more software modules for analyzing data in the storage system. For example, the data may be sensor data from one or more compartments or modules in the system, and an algorithm may be used to monitor one or more parameters. In some examples, the algorithm monitors patterns in the sensor data and can be used to detect anomalies, for example, irregular sensor data from one or more compartments and optionally, alert a user through an HMI. As another example, the data may be an item of information or sequencing data and an algorithm may be used to convert the data to another format (e.g., convert an item of information to a nucleic acid sequence, or vice versa). In some examples, the algorithm comprises an error correction scheme that can be used to correct errors that have occurred during processes in the data storage system.

A system for data storage may comprise a synthesizer unit 310. A synthesizer unit can be used to synthesize a plurality of polynucleotides encoding digital information. In some instances, a synthesizer unit generates the plurality of molecules on the at least one locus of the at least one active surface. In some instances, the system comprises more than one synthesizer units 310. In some instances, the synthesizer unit 310 comprises a flow cell assembly for processing biomolecules. In some instances, the synthesizer unit 310 comprises a deposition chamber for depositing one or more droplets on a solid support. Polynucleotides may be synthesized using a method provided herein or any other suitable synthesis method known in the art. The fluidic and/or electronic control of polynucleotide synthesis in the synthesizer unit 310 may be performed by a controller 335. In some instances, the electronics in the synthesizer unit 310 are in communication with the controller 335. In some instances, the synthesizer unit 310 has an input for receiving DNA sequences. In some instances, the synthesizer unit 310 has an input for receiving fluids for polynucleotide synthesis. In some instances, the synthesizer unit 310 has an output for eluting synthesized polynucleotides. In some instances, the synthesized polynucleotides are transferred to another component of the system, such as, by way of non-limiting example, a storage unit, an amplification chamber, or a sequencing unit.

A flow cell assembly, or a system or platform comprising a flow cell assembly, may be connected to, part of, or coextensive with one or more components of the system, such as the synthesizer unit 310, storage unit 315, amplification unit 320, or sequencer unit 325. In some examples, once the polynucleotides are cleaved from the surface, they are collected and transferred to another component of the system, such as, by way of non-limiting example, storage unit 315, amplification unit 320, or sequencer unit 325. In some instances, the flow cell assembly is oriented to maximize the recovery of liquid, for example, by adjusting one or more angles. Further, an apparatus comprising at least one logic element for performing one or more operations of a biomolecule processing platform or transfer, as provided herein may be in communication with or may be part of a controller 335 of a larger data storage system.

A synthesizer unit may comprise a solid support. The solid support may comprise a surface for generating or synthesizing polynucleotides. The solid support may comprise a CMOS chip. In some instances, the solid support, the surface, or both comprise a material described herein. In some instances, the material comprises a metal or organic polymer. In some instances, the material comprises steel (e.g., stainless steel) or other metal alloy. In some instances, the material comprises polyethylene, polypropylene, or other polymer. In some instances, the struture comprises a flexible material, such as those provided herein. Exemplary flexible materials include, without limitation, modified nylon, unmodified nylon, nitrocellulose, and polypropylene. In some instances, the materials comprise a rigid material, such as those provided herein. Exemplary rigid materials include, without limitation, glass, fuse silica, silicon, silicon dioxide, silicon nitride, plastics (for example, polytetrafluoroethylene, polypropylene, polystyrene, polycarbonate, and blends thereof, and metals (for example, steel, gold, platinum). In some instances, materials disclosed herein may be fabricated from a material comprising silicon, polystyrene, agarose, dextran, cellulosic polymers, polyacrylamides, polydimethylsiloxane (PDMS), glass, or any combination thereof. In some examples, materials disclosed herein are manufactured with a combination of materials listed herein or any other suitable material known in the art.

In some instances, the solid support has varying dimensions. In some instances, a size of the solid support is between about 40 and 120 mm by between about 25 and 100 mm. In some instances, a size of the solid support is about 80 mm by about 50 mm. In some instances, a width of a solid support is at least or about 10 mm, 20 mm, 40 mm, 60 mm, 80 mm, 100 mm, 150 mm, 200 mm, 300 mm, 400 mm, 500 mm, or more than 500 mm. In some instances, a height of a solid support is at least or about 10 mm, 20 mm, 40 mm, 60 mm, 80 mm, 100 mm, 150 mm, 200 mm, 300 mm, 400 mm, 500 mm, or more than 500 mm. In some instances, the solid support has a planar surface area of at least or about 100 mm²; 200 mm²; 500 mm²; 1,000 mm²; 2,000 mm²; 4,500 mm²; 5,000 mm²; 10,000 mm²; 12,000 mm²; 15,000 mm²; 20,000 mm²; 30,000 mm²; 40,000 mm²; 50,000 mm² or more. In some instances, the thickness of the solid support is between about 50 mm and about 2000 mm, between about 50 mm and about 1000 mm, between about 100 mm and about 1000 mm, between about 200 mm and about 1000 mm, or between about 250 mm and about 1000 mm. Non-limiting examples thickness of the solid support include 275 mm, 375 mm, 525 mm, 625 mm, 675 mm, 725 mm, 775 mm and 925 mm. In some instances, the thickness of the solid support is at least or about 0.5 mm, 1.0 mm, 1.5 mm, 2.0 mm, 2.5 mm, 3.0 mm, 3.5 mm, 4.0 mm, or more than 4.0 mm.

In some instances, two or more solid supports are assembled. In some instances, solid supports are interfaced together on a larger unit. Interfacing may comprise exchange of fluids, electrical signals, or other medium of exchange between solid supports. This unit is capable of interface with any number of servers, computers, or networked devices. For example, a plurality of solid support is integrated onto a rack unit, which is conveniently inserted or removed from a server rack. The rack unit may comprise any number of solid supports. In some instances, the rack unit comprises at least 1, 2, 5, 10, 20, 50, 100, 200, 500, 1000, 2000, 5000, 10,000, 20,000, 50,000, 100,000 or more than 100,000 solid supports. In some instances, two or more solid supports are not interfaced with each other. Polynucleotides (and the information stored in them) present on solid supports can be accessed from the rack unit. Access includes removal of polynucleotides from solid supports, direct analysis of polynucleotides on the solid support, or any other method which allows the information stored in the polynucleotides to be manipulated or identified. Information in some instances is accessed from a plurality of racks, a single rack, a single solid support in a rack, a portion of the solid support, or a single locus on a solid support. In various instances, access comprises interfacing polynucleotides with additional devices such as mass spectrometers, HPLC, sequencing instruments, PCR thermocyclers, or other device for manipulating polynucleotides. Access to nucleic acid information in some instances is achieved by cleavage of polynucleotides from all or a portion of a solid support. Cleavage in some instances comprises exposure to chemical reagents (ammonia or other reagent), electrical potential, radiation, heat, light, acoustics, or other form of energy capable of manipulating chemical bonds. In some examples, one or more orientations of the flow cell has been optimized to maximize a liquid comprising the polynucleotides that can be recovered from the flow cell. In some instances, cleavage occurs by charging one or more electrodes in the vicinity of the polynucleotides. In some instances, electromagnetic radiation in the form of UV light is used for cleavage of polynucleotides. In some instances, a lamp is used for cleavage of polynucleotides, and a mask mediates exposure locations of the UV light to the surface. In some instances, a laser is used for cleavage of polynucleotides, and a shutter opened/closed state controls exposure of the UV light to the surface. In some instances, access to nucleic acid information (including removal/addition of racks, solid supports, reagents, polynucleotides, or other component) is completely automated.

Solid supports as described herein comprise an active area. In some instances, the active area comprises regions, cells, features, or loci for generating or synthesizing polynucleotides, as illustrated for example, in FIG. 1B. The solid supports with surfaces comprising polynucleotides may be referred to as active surfaces, while a surface without polynucleotides may be referred to as inactive surfaces. In some instances, the active area or surface is formed at least in part by a perimeter surface of a seal juxtaposed to one or more surfaces of substrates that are functionalized for association with biomolecules. In some instances, the active area comprises regions or loci for association with biomolecules. In some instances, the active areas, e.g., inner region of loci as shown in FIG. 1B, comprising polynucleotides on an active surface may be transferred to inner region of loci on an inactive surface. In some instances, the regions or loci are addressable. In some examples, the regions or loci are addressable through an electrode.

In some instances, the solid support has a number of sites (e.g., loci or features) or positions for polynucleotides generation or synthesis. In some instances, the solid support may be used to storage of polynucleotides. In some instances, the solid support comprises up to or about 10,000 by 10,000 positions in an area. In some instances, the solid support comprises between about 1000 and 20,000 by between about 1000 and 20,000 positions in an area. In some instances, the solid support comprises at least or about 10, 30, 50, 75, 100, 200, 300, 400, 500, 1000, 2000, 3000, 4000, 5000, 6000, 7000, 8000, 9000, 10,000, 12,000, 14,000, 16,000, 18,000, 20,000 positions by least or about 10, 30, 50, 75, 100, 200, 300, 400, 500, 1000, 2000, 3000, 4000, 5000, 6000, 7000, 8000, 9000, 10,000, 12,000, 14,000, 16,000, 18,000, 20,000 positions in an area. In some instances, the area is up to 0.25, 0.5, 0.75, 1.0, 1.25, 1.5, or 2.0 inches squared. In some instances, the solid support comprises loci having a pitch of at least or about 0.1, 0.2, 0.25, 0.3, 0.4, 0.5, 1.0, 1.5, 2.0, 2.5, 3.0, 3.5, 4.0, 4.5, 5, 6, 7, 8, 9, 10, or more than 10 μm. In some instances, the solid support comprises loci having a pitch of about 5 μm. In some instances, the solid support comprises loci having a pitch of about 2 μm. In some instances, the solid support comprises loci having a pitch of about 1 μm. In some instances, the solid support comprises loci having a pitch of about 0.2 μm. In some instances, the solid support comprises loci having a pitch of about 0.2 μm to about 10 μm, about 0.2 to about 8 μm, about 0.5 to about 10 μm, about 1 μm to about 10 μm, about 2 μm to about 8 μm, about 3 μm to about 5 μm, about 1 μm to about 3 μm or about 0.5 μm to about 3 μm. In some instances, the solid support comprises loci having a pitch of about 0.1 μm to about 3 μm.

In some instances, the solid support can be used for information storage. The information may be encoded in polynucleotides which may be storage. In some instances, the solid support comprises a high capacity for storage of data. For example, the capacity of the solid support is at least or about 1, 2, 3, 4, 5, 6, 7, 8, 9, 10, 20, 50, 100, 200, 300, 400, 500, 600, 700, 800, 900, 1000, or more than 1000 petabytes. In some instances, the capacity of the solid support is between about 1 to about 10 petabytes or between about 1 to about 100 petabytes. In some instances, the capacity of the solid support is about 100 petabytes. In some examples, the polynucleotides are stored for a time on the solid support, and subsequently extracted from the solid support using the systems and methods provided herein (e.g., FIGS. 1A-1B). In some instances, once the polynucleotides are extracted from the solid support, the solid support may be reused for polynucleotide synthesis. For example, polynucleotides on a solid support may be stored for days, months, or years, and subsequently extracted from the solid support. The polynucleotides may be extracted from a solid support by providing conditions for cleavage from the solid support. In some examples, polynucleotides may be extracted from a solid support using a flow cell for recovery of information whole or in-part, or quality control of the polynucleotides. In some examples, one or more orientations of the flow cell has been optimized to maximize a liquid comprising the polynucleotides that can be recovered from the flow cell. In some examples, polynucleotides may be extracted from a solid support by contacting the solid support with an empty or inactive solid support as illustrated herein for recovery of information whole or in-part, or quality control of the polynucleotides.

In some instances, the data is stored as arrays of packets as droplets. In some examples, the arrays of packets are addressable packets. In some examples, the packets are addressable using an electrode. In some instances, the data is stored as arrays of packets as droplets on a spot. In some instances, the data is stored as arrays of packets as dry wells. In some instances, the arrays comprise at least or about 1, 2, 3, 4, 5, 6, 7, 8, 9, 10, 20, 50, 100, 200, or more than 200 gigabytes of data. In some instances, the arrays comprise at least or about 1, 2, 3, 4, 5, 6, 7, 8, 9, 10, 20, 50, 100, 200, or more than 200 terabytes of data. In some instances, an item of information is stored in a background of data. For example, an item of information encodes for about 10 to about 100 megabytes of data and is stored in 1 petabyte of background data. In some instances, an item of information encodes for at least or about 1, 10, 20, 30, 40, 50, 60, 70, 80, 90, 100, 150, 200, 300, 400, 500, or more than 500 megabytes of data and is stored in 1, 10, 20, 30, 40, 50, 60, 70, 80, 90, 100, 150, 200, 300, 400, 500, or more than 500 petabytes of background data.

Provided herein is a data storage system comprising a solid support, where following the generation or synthesis, the polynucleotides are collected in packets as one or more droplets. In some instances, the polynucleotides are collected in packets as one or more droplets and stored. In some instances, a number of droplets is at least or about 1, 10, 20, 50, 100, 200, 300, 500, 1000, 2500, 5000, 75000, 10,000, 25,000, 50,000, 75,000, 100,000, 1 million, 5 million, 10 million, 25 million, 50 million, 75 million, 100 million, 250 million, 500 million, 750 million, or more than 750 million droplets. In some instances, a droplet volume comprises 5, 10, 15, 20, 25, 30, 35, 40, 45, 50, 55, 60, 65, 70, 75, 80, 85, 90, 95, 100, or more than 100 μm (micrometer) in diameter. In some instances, a droplet volume comprises 1-100 μm, 10-90 μm, 20-80 μm, 30-70 μm, or 40-50 μm in diameter.

In some instances, the polynucleotides that are collected in the packets comprise a similar sequence. In some instances, the polynucleotides further comprise a non-identical sequence to be used as a tag or barcode. For example, the non-identical sequence is used to index the polynucleotides stored on the solid support and to later search for specific polynucleotides based on the non-identical sequence. Exemplary tag or barcode lengths include barcode sequences comprising, without limitation, about 1, 2, 3, 4, 5, 6, 7, 8, 9, 10, 15, 20, 25 or more bases in length. In some instances, the tag or barcode comprise at least or about 10, 50, 75, 100, 200, 300, 400, or more than 400 base pairs in length.

Provided herein is a data storage system comprising a solid support, where the polynucleotides are collected in packets comprising redundancy. For example, the packets comprise about 100 to about 1000 copies of each polynucleotide. In some instances, the packets comprise at least or about 50, 75, 100, 200, 300, 400, 500, 600, 700, 800, 900, 1000, 1200, 1400, 1600, 1800, 2000, or more than 2000 copies of each polynucleotide. In some instances, the packets comprise about 1000X to about 5000X synthesis redundancy. Synthesis redundancy in some instances is at least or about 500X, 1000X, 1500X, 2000X, 2500X, 3000X, 3500X, 4000X, 5000X, 6000X, 7000X, 8000X, or more than 8000X. The polynucleotides that are synthesized using solid support-based methods as described herein comprise various lengths. In some instances, the polynucleotides are synthesized and further stored on the solid support. In some instances, the polynucleotide length is in between about 100 to about 1000 bases. In some instances, the polynucleotides comprise at least or about 10, 20, 30, 40, 50, 60, 70, 80, 90, 100, 125, 150, 175, 200, 225, 250, 275, 300, 325, 350, 375, 400, 425, 450, 475, 500, 600, 700, 800, 900, 1000, 1100, 1200, 1300, 1400, 1500, 1600, 1700, 1800, 1900, 2000, or more than 2000 bases in length.

In some instances, the polynucleotides are deprotected, cleaved, and/or eluted from the synthesizer unit 310 and transferred to another module in the system. In some instances, the polynucleotides are transferred from the synthesizer unit 310 on the solid support. In some instances, a robotic system 330 or fluidic tube is used to transports the polynucleotides to another module in the system. A robotic system 330 may be controlled by a controller 335. A robotic system generally comprises a system for manipulation of a plurality of polynucleotides. In some instances, the robotic system is used to manipulate a structure comprising a plurality of polynucleotides, such as those described herein. Manipulation can comprise, by way of non-limiting example, moving, storing, retrieving, handling, transferring, or any combination thereof. The robotic system may be similar to those used in semiconductor processing to move trays of wafers and chips between processing devices. A robotic system 330 may be used to select and transfer polynucleotides between modules of the system. A robotic system 330 may be used to align one or more surfaces with another surface to transfer information, while maintaining the spatial arrangement and addressability, for example, as generally illustrated in FIG. 1B.

In some examples, a robotic system 335 includes a tag reader to verify a structure in a storage unit 315. In some instances, the robotic system 335 comprises a reader of a tag (e.g., RFID reader, barcode reader, etc.) and the structure in the storage unit 315 comprises a tag (e.g., RFID tag, barcode, etc.). Once verified, the robotic system 330 may transfer the structure to a component of the system. Additionally, the robotic system 330 may transfer the structure to a precise location in a component of the system. In some instances, the robotic system can allow for polynucleotides to be added and/or removed from modules in the data storage system. In some instances, the robotic system allows for a structure comprising a plurality of polynucleotides to be placed and/or retrieved from a location in an identifiable layout in the storage unit 315. The robotic system 330 may be controlled using a controller 335 as further described herein.

In some instances, one or more droplets comprising polynucleotides are used to transfer polynucleotides, for example, from a synthesizer unit 310 to a storage unit 315. In some instances, some or all of the polynucleotides synthesized on a solid support are transferred to a structure for storage. The transfer of polynucleotides one surface to another which can be used to copy information encoded in the polynucleotides may be performed as generally illustrated for example in FIGS. 1A-1B. In some examples, the synthesizer unit 310 is connected to or is coextensive with a system or platform for biomolecule processing. In some examples, the polynucleotides are synthesized on a first substrate and transferred to a second substrate as described herein. In some instances, once the polynucleotides are transferred to the second substrate, the first substrate may be reused for polynucleotide synthesis or generation. In some examples, the polynucleotides are synthesized and/or extracted using a system or platform comprising a flow cell assembly, oriented to maximize the recovery of fluid comprising the polynucleotides. The extracted polynucleotides can be collected in a structure for subsequent storage.

The structure may further comprise a tag, such as those described herein. The tag can comprise a barcode or an RFID tag. In some instances, a plurality of polynucleotides is transferred to a structure in the synthesizer unit 310. In some instances, the plurality of polynucleotides is transferred to a structure from a flow cell assembly, which can be part of a biomolecule processing system. In some instances, a plurality of polynucleotides is transferred to a structure in the storage unit 315. The fluidic and/or electronic control of polynucleotide synthesis in the storage unit 315 may be performed by a controller 335. In some instances, the electronics in the storage unit 315 are in communication with the controller 335. In some instances, the polynucleotides are stored at room temperature in the storage unit 315. In some instances, the system comprises a database or a file system for keeping track of the storage capacity in the storage unit 315. In some examples, the database comprises a control application database. In some instances, the database or the file system is part of the controller 335.

A structure comprising a plurality of polynucleotides can be stored in an identifiable layout in storage unit 315. The identifiable layout may comprise a rack or a plurality of racks, or a variation thereof. The rack may be used to hold one or more structures comprising the plurality of polynucleotides. In some instances, each structure is stored at a fixed location in the identifiable layout. In some instances, the tag comprises information about a location of the structure in the identifiable layout. As an example, a tag (e.g., RFID tag) can encode metadata comprising a location of the structure in the identifiable layout. In some instances, the rack may be located in a data center. In some instances, the rack uses mechanical structures commonly used for mounting conventional computing and data storage resources in rack units. For example, a rack may comprise openings adapted to support disk drives, processing blades, and/or other computer equipment. In some instances, a rack comprises a tag. In some examples, the tag comprises information of the structures stored in/on the rack. In some examples, the tag comprises a list of the structures stored in/on the rack.

In some instances, the system comprises a deposition chamber for preparing one or more surface for transferring information. In some instances, the deposition chamber deposits one or more droplets on one or more regions or loci on a surface (e.g., surface 100 with droplets 115 in FIG. 1A). In some instances, the deposition chamber comprises a humid environment, and one or more droplets form on one or more regions or loci on a surface when exposed to the humid environment (e.g., surface 100 with droplets 115 in FIG. 1A). In some instances, the droplets comprise one or more reagents that can be used to cleave one or more molecules residing on another surface upon contact with the droplets, as described herein.

In some instances, the storage unit 315 may be accessed using a robotic system 330. In some instances, the identifiable layout in the storage unit 315 comprises robotically addressable slots. Each slot may hold a structure comprising a plurality of polynucleotides. In some instances, each slot comprises a width, depth, length, or any combination thereof for accommodating a structure comprising the plurality of polynucleotides. In some instances, a rack comprises a plurality of slots, where each slot holds a structure comprising the plurality of polynucleotides.

The system for storing polynucleotides may further comprise an amplification chamber 320. The amplification unit may be used to amplify the plurality of polynucleotides. In some instances, the system comprises more than one amplification chamber 320. In some instances, a structure is selected from a storage unit 315 and the polynucleotides from the structure are transferred to the amplification chamber 320. In some instances, the polynucleotides from a synthesizer unit 310 are transferred to the amplification chamber 320 for size selection, PCR, or other type of amplification or preparation for storage. Size selection generally involves selecting DNA in the target size and rejecting strands that are much shorter or much longer. In some instances, filters are tuned to capture DNA of a particular size range. In some instances, other methods include PCR, electrophoresis, capture by solid phase bound primers, which are complementary to the end sequences of synthesized oligonucleotides, or the use of an isothermal polymerase. The fluidic and/or electronic control of polynucleotide synthesis in the amplification chamber 320 may be performed by a controller 335. In some instances, the electronics in the amplification chamber 320 are in communication with the controller 335.

The system for storing polynucleotides may further comprise a sequencing unit 325. The sequencing unit 325 may be used to sequence a plurality of polynucleotides. In some instances, the plurality of polynucleotides is transferred from the amplification chamber 320 to the sequencing unit 325. In some instances, the system may comprise additional modules for performing additional sequencing preparation steps. In some examples, the plurality of polynucleotides is transferred from the amplification chamber 320 to the sequencing unit 325 using one or more tubes or the robotic system 330. In some instances, the amplification chamber 320 and the sequencing unit 325 are fluidically coupled. The fluidic and/or electronic control of polynucleotide synthesis in the sequencing unit 325 may be performed by a controller 335. In some instances, the electronics in the sequencing unit 325 are in communication with the controller 335.

In some instances, the system comprises large-scale sequencing of polynucleotides. In some instances, large-scale sequencing comprises dense and highly parallel sequencers. In some instances, the system comprises more than one sequencing unit 325. In some instances, the sequencing unit 325 use centrifugal forces and/or vacuum/pressure to add or evacuate reagents from the sequencing unit 325. In some instances, the sequencing unit 325 is light-based (e.g., with light sources and sensors on chip), nanopore-based (e.g., Oxford Nanopore Technologies (ONT)), or involve other operations (e.g., a light-based method such as PacBio or other sequencing technologies). In some instances, the sequencing unit 325 employs sequencing methods provided herein. In some instances, the sequencing unit 325 uses of nanopores or other electrical sequencing technology that benefits from the bulk fluidics provided by semiconductor fabrication equipment. In some instances, the one or more modules described herein comprises a camera. A camera may be used to capture one or more optical features of polynucleotides in a module. As an example, a camera may be used in a synthesizer unit, a sequencing unit, or both, to capture an optical feature of polynucleotides attached to a surface on a solid support as described herein.

The system for storing polynucleotides can comprise a robotic system 330 as described herein. The robotic system may generally be used to manipulate the polynucleotides in a system. Manipulation can comprise, without limitation, moving, storing, retrieving, handling, transferring, or any combination thereof. In some instances, the robotic system transfers the plurality of polynucleotides between modules in the system. In some examples, the robotic system manipulates (e.g., transfers) the plurality of polynucleotides in structure for storage as described herein. In some instances, the robotic system manipulates (e.g., transfers) the plurality of polynucleotides in a rack. In some examples, the rack comprises a plurality of structures each comprising an RFID tag. In some examples, the rack comprises a plurality of solid supports for synthesis and/or sequencing. In some instances, the robotic system comprises a robotic hand or a robotic picker. In some instances, the robotic system 330 is fully integrated with the storage system control software and/or firmware in the controller 335. In some instances, the robotic system 330 is fully integrated with an external host application. In some instances, the robotic system 330 is fully automated.

The system for storing polynucleotides can comprise a controller 335. The controller may generally be used for controlling modules, components, fluidics, robots, or any combination thereof. The modules, components, fluidics, electronics, robots, or any combination thereof may be used for synthesizing, storing, retrieving, sequencing, and/or amplifying polynucleotides. In some instances, the controller 335 is capable of cataloguing all storage structures loaded, unloaded, and/or stored within a rack. The polynucleotides can encode digital information as described herein. The modules, components, fluidics, electronics, robots, or any combination thereof may be used for performing methods, models, or algorithms, such as encoding or decoding the polynucleotides.

In some instances, the controller 335 controls the physical location of the plurality of polynucleotides. In some instances, the controller 335 provides commands to one or more modules of the system. In some examples, the controller 335 controls robotics (e.g., robotic system 330), actuators, and fluidic valves, or any other equipment of the system. In some instances, the controller 335 allows for synchronizing and controlling the modules for processing and/or transferring polynucleotides. In some examples, the polynucleotides are processed and/or transferred via fluidics. In some examples, the controller 335 controls one or more valves or parameters (e.g., pressure, vacuum, temperature, volume, etc.) in the system for biomolecule processing. In some examples, the controller 335 can be used to orient or adjust the orientation of a flow cell in a system for biomolecule processing. This can allow for flexibility of the system and maximize recovery of material (e.g., polynucleotides). In some examples, the polynucleotides are processed and/or transferred via electronics. In some instances, the controller 335 controls physical parameters in one or more modules, such as, without limitation, pressure, vacuum, temperature, volume (e.g., of fluids), or any combination thereof.

In some instances, the controller 335 invokes an encoder module or a decoder module. In some instances, the encoder module encodes the digital information as a plurality of polynucleotides. In some instances, the encoder module applies one or more codecs, such as those described herein, to the digital information. In some instances, the decoder module decodes the sequences of the plurality of polynucleotides to retrieve the digital information. In some instances, the decoder module applies one or more codecs, such as those described herein, to the sequences of the plurality of polynucleotides. In some instances, the decode module performs reassembly, error correction, and outputs digital information (e.g., binary data). In some instances, the output comprising digital information is transferred to an operating system and/or a file system. The output may be provided on a display, such as a graphical user interface (GUI), or any other suitable display such as those described herein, for providing the digital information. In some instances, the controller 335 is implemented on one or more software modules, such as those described herein. In some instances, the controller 335 responds to commands from an operating system, such as those described herein.

An encoder module generally encodes the digital information as a plurality of polynucleotides. An encoder can apply an encoding scheme to digital information. In some instances, the encoding scheme comprises codecs for encoding binary data as polynucleotide sequences (e.g., inner codec). In some instances, the encoding scheme comprises an error correction code (ECC) (e.g., outer codec). In some instances, employing a flow cell optimized for maximum recovery of material from a substrate decreases the need for error correction, since less material is lost between transfer of material. In some cases, the encoding scheme is designed and implemented to allow streaming read and write API access. In some cases, the encoding scheme is designed and implemented to match the streaming of the systems and methods for digital storage described herein.

The encoding scheme can generally comprise one or more operations. The one or more operations can comprise one or more operation to manipulate or transform data (e.g., digital information). The one or more operations can comprise by way of non-limiting example, splitting, shuffling, concatenating, transposing, translating, duplicating, labeling (e.g., using an index) data or a part of the data, or any combination thereof.

In some instances, the outer codec comprises an error correction code (ECC) or scheme, such as, without limitation, a Reed-Solomon (RS) code, a low-density parity-check (LDPC) code, a polar code, a turbo code, or any variation thereof. This outer codec is used for spreading the digital or binary data to be stored over many oligonucleotides. In some instances, spreading the data builds redundancy to correct for erasures (e.g., lost oligos). In some further embodiments, spreading the data also builds redundancy to correct errors from an inner codec. In some instances, the methods for encoding digital or binary data in a plurality of nucleotide sequences comprise an inner codec. In some instances, the inner codec is applied to the binary data. In some instances, the inner codec is applied to the binary data from the ECC. In some instances, the inner codec is applied to the lanes of the binary data. In some instances, the inner codec is applied to binary data that has been shuffled.

In some instances, the encoding scheme comprises an inner codec. In some instances, an inner codec is applied to encode the binary data as a polynucleotide sequence. The inner codec is used to transform digital or binary data into nucleotide bases. In some instances, the inner codec is capable of correcting deletion, substitution, or insertion errors, or any combination thereof. In some further embodiments, the inner codec is used to validate oligos and discard any suspicious oligos to avoid contaminating the outer decoding. The inner codec further encodes the indices, which can allow for efficient clustering during decoding. In some instances, the encoding scheme adds redundancy across the plurality of oligonucleotide sequences. In some instances, the inner codec comprises generating base candidates. In some instances, base candidates are generated using a codebook, a lookup table, a hash, or any suitable method known in the art. In some instances, the inner codec further comprises a base repetition check. In some instances, the inner codec further comprises performing GC filtering.

A decoder module generally decodes the sequences of the plurality of polynucleotides to retrieve the digital information. A decoder can apply a decoding scheme to the sequences of the plurality of polynucleotides. In some instances, a decoding scheme comprises an inner codec, an outer codec (e.g., ECC), or a combination thereof. In some instances, the decoding scheme decodes a plurality of polynucleotide sequences to generate an output comprising digital information. In some instances, the decoding scheme comprises undoing operations in the encoding scheme. In some examples, the operations comprise, without limitation, splitting, shuffling, concatenating, transposing, translating, duplicating, labeling (e.g., using an index) data or a part of the data, or any combination thereof.

A digital output from a sequencer unit comprising sequences of the plurality of polynucleotides may be provided to the decoding module. In some instances, the decoder module orders, clusters, and/or aligns sequences of the plurality of polynucleotides. In some examples, the decoder module comprises an alignment algorithm, such as with limitation, a pairwise alignment algorithm, a multi-sequence alignment algorithm, or any other suitable algorithm.

In some instances, decoding scheme comprise an inner codec. In some instances, the inner codec is applied to the plurality of polynucleotide sequences. The inner codec is used to transform the polynucleotide sequences into digital or binary data. In some instances, the inner codec is capable of correcting deletion, substitution, or insertion errors, or any combination thereof. In some further embodiments, the inner codec is used to validate oligos and discard any suspicious oligos to avoid contaminating the outer decoding. In some instances, the inner codec allows for efficient decoding using the indices.

An inner codec comprising a decoding scheme can be applied to the plurality of polynucleotide sequences. In some instances, the inner codec transforms each of the plurality of polynucleotide sequences into binary data. In some instances, the inner codec is applied to a plurality of polynucleotides that have been sequenced. In some examples, the plurality of clustered have been ordered, clustered, aligned, or any combination thereof.

In some instances, the inner codec comprises a greedy algorithm. A greedy algorithm generally takes into account transitions from only the most probably state as it decodes each bit position in a sequence. In some instances, the inner codec comprises a maximum likelihood (ML) algorithm. A ML algorithm generally takes into account transitions from all states as it decodes each bit position in a sequence In some instances, the inner codec comprises a mixed greedy ML algorithm. A mixed greedy ML algorithm can generally take into account transitions from a plurality of states as it decodes each bit position in a sequence. In some instances, the inner codec comprises a beam search decoder or a random sampling decoder (e.g., pure sampling decoder, a top-K sampling decoder, etc.). In some cases, a beam search decoder or a random sampling decoder provides a diversity of candidate states compared to a greedy decoder. In some instances, the inner codec further comprises a checksum. In some instances, the inner codec comprises a hash (e.g., SHA-256). In some instances, the hash verifies that the data was correctly decoded. In some instances, by using a hash at the end (after the ECC), the encoding and decoding are performed as a stream. In some instances, this can limit memory use to only temporary buffers.

In some instances, the decoding module comprises an outer codec (e.g., ECC). In some instances, the plurality of nucleotide sequences is decoded into digital or binary data. In some instances, an outer codec (e.g., ECC) is applied to the digital or binary data. In some instances, the outer codec comprises an ECC used to encode the data (e.g., binary data). In some instances, the ECC comprises a Reed-Solomon (RS) code, a LDPC code, a polar code, a turbo code, or any combination thereof. In some instances, the decoding scheme comprises soft decoding. Soft decoding generally refers to decoding by considering a range of possible values (e.g., using probability estimates).

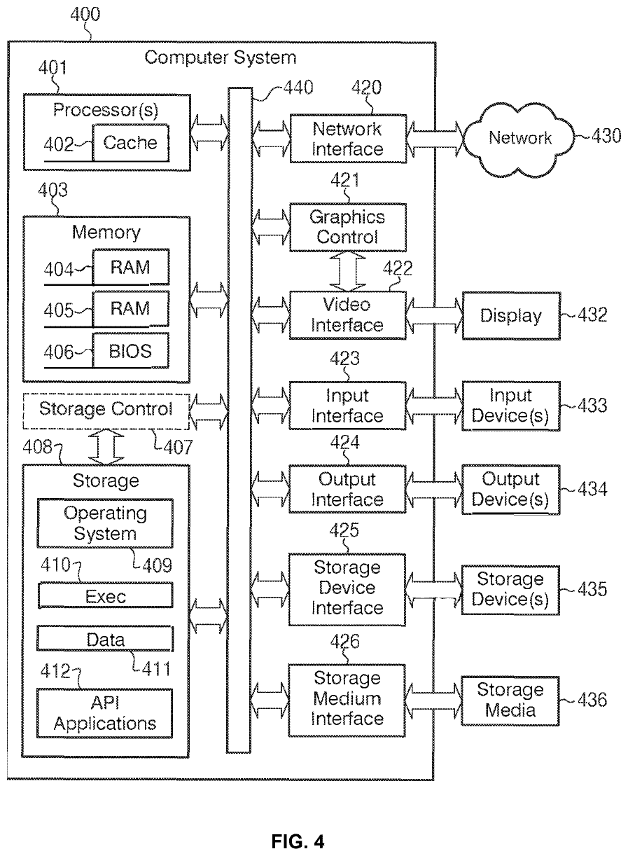

The data storage and transfer system as generally illustrated in FIG. 3 may be part of an in silico computing system. A system for transferring information can generally comprise one or more of at least one processing unit; a memory in communication with the at least one processing unit; an organic storage in communication with the at least one processing unit and the memory; or instructions stored in the memory and executed on the one or more processing units that cause the system to transfer the information in the organic storage through one or more operations. Referring to FIG. 4, a block diagram is shown depicting an exemplary machine that includes a system 400 (e.g., a processing, computing, and/or storage system) within which a set of instructions can execute for causing a device to perform or execute any one or more of the aspects and/or methodologies for static code scheduling of the present disclosure. The components in FIG. 4 are examples only and may not limit the scope of use or functionality of any hardware, software, embedded logic component, or a combination of two or more such components implementing particular embodiments.

The organic storage can comprise at least one active surface comprising a plurality of molecules encoding information. The plurality of molecule can reside on one or more loci. For example, referring to FIG. 1B, the organic storage can comprise a surface 140 with one or more loci, where a plurality of molecules 125 reside in the inner region 105 of the loci. In some instances, the organic storage can comprise at least one inactive surface comprising one or more droplets. The one or more droplets can reside on one or more loci. In some examples, referring to FIG. 1B, the organic storage comprises a surface 100 with one or more loci, where one or more droplets 115 reside in the inner region 105 of the loci. The one or more operations can comprise contacting the plurality of biomolecules residing at least one locus of the at least one active surface with at least one droplet of the at least one inactive surface or transferring the plurality of biomolecules at the at least one locus to the at least one droplet of the at least one inactive surface.

The information may or may not be transferred from a surface 140 to another surface 100 in the organic storage based on the length of storage. In some instances, the polynucleotides encoding information may not be transferred if information is stored for seconds, minutes, hours, days, weeks, or months. In some instances, the polynucleotides encoding information may not be transferred if information is stored for at most minutes, hours, days, weeks, or months. In some instances, the polynucleotides encoding information may be transferred if information is stored for days, weeks, months, years, or decades. In some instances, the polynucleotides encoding information may be transferred if information is stored for at least days, weeks, months, years, or decades. In some instances, transferring the polynucleotides comprises transferring the polynucleotides to a more cost effective substrate or a substrate suitable for long term storage.

A system 400 may include one or more processors 401, a memory 403, and a storage 408 that communicate with each other, and with other components. The one or more processors 401, a memory 403, and a storage 408 that communicate with each other, and with other components via a bus 440. The bus 440 may also link a display 432, one or more input devices 433 (which may, for example, include a keypad, a keyboard, a mouse, a stylus, etc.), one or more output devices 434, one or more storage devices 435, and various tangible storage media 436. All of these elements may interface directly or via one or more interfaces or adaptors to the bus 440. For instance, the various tangible storage media 436 can interface with the bus 440 via storage medium interface 426. A system 400 may have any suitable physical form, including in silico forms, organic forms, or both. For examples a system 400 may have any suitable in silico physical form, including but not limited to one or more integrated circuits (ICs), printed circuit boards (PCBs), mobile handheld devices (such as mobile telephones or PDAs), laptop or notebook computers, distributed computer systems, cloud computer systems, computing grids, or servers. A system 400 may further have any suitable organic form, including but not limited to organic storage or organic memory. An organic form may comprise, in some examples, substrates or compartments for storing molecules encoding information. For example, a storage media 436 may comprise a plurality of molecules, which may be stored on a in one or more storage device 435, such as a substrate or container suitable for storage of the plurality of the molecules. The molecules can, in some instances, comprise a plurality of polynucleotides or a plurality of polypeptides encoding information.

A system 400 includes one or more processor(s) 401 (e.g., central processing units (CPUs), general purpose graphics processing units (GPGPUs), or quantum processing units (QPUs)) that carry out functions. Processor(s) 401 optionally contains a cache memory unit 402 for temporary local storage of instructions, data, or computer addresses. Processor(s) 401 are configured to assist in execution of computer readable instructions. A system 400 may provide functionality for the components depicted in FIG. 4 as a result of the processor(s) 401 executing non-transitory, processor-executable instructions embodied in one or more tangible computer-readable storage media, such as memory 403, storage 408, storage devices 435, and/or storage medium 436. The computer-readable media may store software that implements particular embodiments, and processor(s) 401 may execute the software. Memory 403 may read the software from one or more other computer-readable media (such as mass storage device(s) 435, 436) or from one or more other sources through a suitable interface, such as network interface 420. The software may cause processor(s) 401 to carry out one or more processes or one or more steps of one or more processes described or illustrated herein. Carrying out such processes or steps may include defining data structures stored in memory 403 and modifying the data structures as directed by the software.

The memory 403 may include various components (e.g., machine readable media) including, but not limited to, a random access memory component (e.g., RAM 404) (e.g., static RAM (SRAM), dynamic RAM (DRAM), ferroelectric random access memory (FRAM), phase-change random access memory (PRAM), etc.), a read-only memory component (e.g., ROM 405), and any combinations thereof. ROM 405 may act to communicate data and instructions unidirectionally to processor(s) 401, and RAM 404 may act to communicate data and instructions bidirectionally with processor(s) 401. ROM 405 and RAM 404 may include any suitable tangible computer-readable media described below. In one example, a basic input/output system 406 (BIOS), including basic routines that help to transfer information between elements within computer system 400, such as during start-up, may be stored in the memory 403.

Fixed storage 408 is connected bidirectionally to processor(s) 401, optionally through storage control unit 407. Fixed storage 408 provides additional data storage capacity and may also include any suitable tangible computer-readable media described herein. Storage 408 may be used to store operating system 409, executable(s) 410, data 411, applications 412 (application programs), and the like. Storage 408 can also include in silico storage media such as, but not limited to an optical disk drive, a solid-state memory device (e.g., flash-based systems), or a combination of any of the above. Storage 408 can further include organic storage media such as, but not limited molecules, such as a plurality of polynucleotides or a plurality of polypeptides. Information in storage 408 may, in appropriate cases, be incorporated as virtual memory in memory 403.

In one instance, storage device(s) 435 may be removably interfaced with the system 400 via a storage device interface 425. As an example, storage device(s) 435 in an in silico form may be interfaced with the system 400 via an external port connector (not shown). In a further example, storage device(s) 435 housing storage media 436 in an organic form may be interfaced (e.g., interfaces 425 or 426) with the system 400 by way of one or more instruments for storing or extracting information stored in molecules. The one or more instruments may comprise, but are not limited to a robotic system for physically moving one or more devices (e.g., substrates or containers) holding the molecules. The one or more instruments may further comprise a synthesizer, a sequencer, or both, which may be used to store information in or extract information from molecules. Particularly, storage device(s) 435 and an associated machine-readable medium, which may be in silico form, organic form, or both, may provide non-volatile and/or volatile storage of machine-readable instructions, data structures, program modules, and/or other data for the system 400. In one example, software may reside, completely or partially, within a machine-readable medium on storage device(s) 435. In another example, software may reside, completely or partially, within processor(s) 401.

Bus 440 connects a wide variety of subsystems. Herein, reference to a bus may encompass one or more digital signal lines serving a common function, where appropriate. Bus 440 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

A system 400 may also include an input device 433. In one example, a user of the system 400 may enter commands and/or other information into the system 400 via input device(s) 433. In some examples, a user of the system 400 may transfer the information, e.g., data 411, to be stored on one or more storage devices 435 through the input device 433. The information may comprise, in some instances, a string of symbols that may be directly used by one or more instruments of a storage device interface 425. The information may comprise, in some further instances, a string of symbols that may be mapped to a second string of symbols (e.g., text to binary, binary to nucleic acid sequences or peptide sequences, etc.), where the second string of symbols may be used by one or more instruments of a storage device interface 425. The one or more instruments, for example, a synthesizer, may use a string of symbols to generate a plurality of biomolecules for storage on a storage device 435. Examples of an input device(s) 433 include, but are not limited to, an alpha-numeric input device (e.g., a keyboard), a pointing device (e.g., a mouse or touchpad), a touchpad, a touch screen, a multi-touch screen, a joystick, a stylus, a gamepad, an audio input device (e.g., a microphone, a voice response system, etc.), an optical scanner, a video or still image capture device (e.g., a camera), and any combinations thereof. In some embodiments, the input device is a Kinect, Leap Motion, or the like. Input device(s) 433 may be interfaced to bus 440 via any of a variety of input interfaces 423 (e.g., input interface 423) including, but not limited to, serial, parallel, game port, USB, FIREWIRE, THUNDERBOLT, or any combination of the above.

In particular embodiments, when computer system 400 is connected to network 430, computer system 400 may communicate with other devices, specifically mobile devices and enterprise systems, distributed computing systems, cloud storage systems, cloud computing systems, and the like, connected to network 430. In some embodiments, the system 400 may communicate with one or more components of a system of DNA data storage (e.g., FIG. 3). For example, the computing system 400 may communicate with (e.g., control or manage) the robotic system 330. In some embodiments, the system 400 may comprise or may be integrated with the DNA data storage system (e.g., FIG. 3). For example, the synthesizer unit 310, the amplification unit 320, or the sequencer unit 325 may serve as an interface for transferring the data between storage and the system, as shown in FIG. 4. In a further example, the storage device(s) 435 of a system may comprise a storage unit 315 of a DNA data storage system.

Communications to and from system 400 may be sent through network interface 420. For example, network interface 420 may receive incoming communications (such as requests or responses from other devices) in the form of one or more packets (such as Internet Protocol (IP) packets) from network 430, and system 400 may store the incoming communications in memory 403 for processing. Computer system 400 may similarly store outgoing communications (such as requests or responses to other devices) in the form of one or more packets in memory 403 and communicated to network 430 from network interface 420. In some embodiments, the system 400 has access to a tag on a structure (e.g., substrate or container) for data storage, such as, for example, a barcode or an RFID tag. In some embodiments, the system 400 manages the information of the tag, as well as an associated file system or database. Processor(s) 401 may access these communication packets stored in memory 403 for processing.

Examples of the network interface 420 include, but are not limited to, a network interface card, a modem, and any combination thereof. Examples of a network 430 or network segment 430 include, but are not limited to, a distributed computing system, a cloud computing system, a wide area network (WAN) (e.g., the Internet, an enterprise network), a local area network (LAN) (e.g., a network associated with an office, a building, a campus or other relatively small geographic space), a telephone network, a direct connection between two computing devices, a peer-to-peer network, and any combinations thereof. A network, such as network 430, may employ a wired and/or a wireless mode of communication. In general, any network topology may be used.

Information and data can be displayed through a display 432. Examples of a display 432 include, but are not limited to, a cathode ray tube (CRT), a liquid crystal display (LCD), a thin film transistor liquid crystal display (TFT-LCD), an organic liquid crystal display (OLED) such as a passive-matrix OLED (PMOLED) or active-matrix OLED (AMOLED) display, a plasma display, and any combinations thereof. The display 432 can interface to the processor(s) 401, memory 403, and fixed storage 408, as well as other devices, such as input device(s) 433, via the bus 440. The display 432 is linked to the bus 440 via a video interface 422, and transport of data between the display 432 and the bus 440 can be controlled via the graphics control 421. In some embodiments, the display is a video projector. In some embodiments, the display is a head-mounted display (HMD) such as a VR headset. In further embodiments, suitable VR headsets include, by way of non-limiting examples, HTC Vive, Oculus Rift, Samsung Gear VR, Microsoft HoloLens, Razer OSVR, FOVE VR, Zeiss VR One, Avegant Glyph, Freefly VR headset, and the like. In still further embodiments, the display is a combination of devices such as those disclosed herein.

In addition to a display 432, computer system 400 may include one or more other peripheral output devices 434 including, but not limited to, an audio speaker, a printer, a storage device, and any combinations thereof. In some instances, a peripheral output device 434 may correspond to a tag on a structure, such as, for example, an RFID tag. Such peripheral output devices may be connected to the bus 440 via an output interface 424. Examples of an output interface 424 include, but are not limited to, a serial port, a parallel connection, a USB port, a FIREWIRE port, a THUNDERBOLT port, and any combinations thereof.

In addition or as an alternative, computer system 400 may provide functionality as a result of logic hardwired or otherwise embodied in a circuit, which may operate in place of or together with software to execute one or more processes or one or more steps of one or more processes described or illustrated herein. Reference to software in this disclosure may encompass logic, and reference to logic may encompass software. Moreover, reference to a computer-readable medium may encompass a circuit (such as an IC) storing software for execution, a circuit embodying logic for execution, or both, where appropriate. The present disclosure encompasses any suitable combination of hardware, software, or both.

Those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by one or more processor(s), or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In accordance with the description herein, suitable computing devices include, by way of non-limiting examples, server computers, desktop computers, laptop computers, notebook computers, sub-notebook computers, netbook computers, netpad computers, set-top computers, media streaming devices, handheld computers, Internet appliances, mobile smartphones, tablet computers, personal digital assistants, video game consoles, and vehicles.

In some embodiments, the computing device includes an operating system configured to perform executable instructions. The operating system is, for example, software, including programs and data, which manages the device's hardware and provides services for execution of applications. Those of skill in the art will recognize that suitable server operating systems include, by way of non-limiting examples, FreeBSD, OpenBSD, NetBSD®, Linux, Apple® Mac OS X Server®, Oracle® Solaris®, Windows Server®, and Novell® NetWare®. Those of skill in the art will recognize that suitable personal computer operating systems include, by way of non-limiting examples, Microsoft® Windows®, Apple® Mac OS X®, UNIX®, and UNIX-like operating systems such as GNU/Linux®. In some embodiments, the operating system is provided by cloud computing. Those of skill in the art will also recognize that suitable mobile smartphone operating systems include, by way of non-limiting examples, Nokia® Symbian® OS, Apple® iOS®, Research In Motion® BlackBerry OS®, Google® Android®, Microsoft® Windows Phone® OS, Microsoft® Windows Mobile® OS, Linux®, and Palm® WebOS®. Those of skill in the art will also recognize that suitable media streaming device operating systems include, by way of non-limiting examples, Apple TV®, Roku®, Boxee®, Google TV®, Google Chromecast®, Amazon Fire®, and Samsung® HomeSync®. Those of skill in the art will also recognize that suitable video game console operating systems include, by way of non-limiting examples, Sony® PS3®, Sony® PS4®, Microsoft® Xbox 360®, Microsoft Xbox One, Nintendo® Wii®, Nintendo® Wii U®, and Ouya®.

### Storage Medium

The platforms, systems, and methods disclosed herein include storage media. In some instances, the storage media includes one or more non-transitory computer readable storage media encoded with a program including instructions executable by the operating system of an optionally networked computing device. In further embodiments, a computer readable storage medium is a tangible component of a computing device. In still further embodiments, a computer readable storage medium is optionally removable from a computing device. In some embodiments, a computer readable storage medium includes, by way of non-limiting examples, CD-ROMs, DVDs, flash memory devices, solid state memory, magnetic disk drives, magnetic tape drives, optical disk drives, distributed computing systems including cloud computing systems and services, and the like. In some cases, the program and instructions are permanently, substantially permanently, semi-permanently, or non-transitorily encoded on the media. In some instances, the storage media is in an organic form, such as molecules. The molecules may comprise biological molecules, such as, but not limited to polynucleotides or polypeptides.

### Computer Program

In some embodiments, the platforms, systems, media, and methods disclosed herein include at least one computer program, or use of the same. A computer program includes a sequence of instructions, executable by one or more processor(s) of the computing device's CPU, written to perform a specified task. Computer readable instructions may be implemented as program modules, such as functions, objects, Application Programming Interfaces (APIs), computing data structures, and the like, that perform particular tasks or implement particular abstract data types. In light of the disclosure provided herein, those of skill in the art will recognize that a computer program may be written in various versions of various languages. The functionality of the computer readable instructions may be combined or distributed as desired in various environments. In some embodiments, a computer program comprises one sequence of instructions. In some embodiments, a computer program comprises a plurality of sequences of instructions. In some embodiments, a computer program is provided from one location. In other embodiments, a computer program is provided from a plurality of locations. In various embodiments, a computer program includes one or more software modules. In various embodiments, a computer program includes, in part or in whole, one or more web applications, one or more mobile applications, one or more standalone applications, one or more web browser plug-ins, extensions, add-ins, or add-ons, or combinations thereof.

In some embodiments, the platforms, systems, media, and methods disclosed herein include software, server, and/or database modules, or use of the same. In view of the disclosure provided herein, software modules are created by techniques known to those of skill in the art using machines, software, and languages known to the art. The software modules disclosed herein are implemented in a multitude of ways. In various embodiments, a software module comprises a file, a section of code, a programming object, a programming structure, a distributed computing resource, a cloud computing resource, or combinations thereof. In further various embodiments, a software module comprises a plurality of files, a plurality of sections of code, a plurality of programming objects, a plurality of programming structures, a plurality of distributed computing resources, a plurality of cloud computing resources, or combinations thereof. In various embodiments, the one or more software modules comprise, by way of non-limiting examples, a web application, a mobile application, a standalone application, and a distributed or cloud computing application. In some embodiments, software modules are in one computer program or application. In other embodiments, software modules are in more than one computer program or application. In some embodiments, software modules are hosted on one machine. In other embodiments, software modules are hosted on more than one machine. In further embodiments, software modules are hosted on a distributed computing platform such as a cloud computing platform. In some embodiments, software modules are hosted on one or more machines in one location. In other embodiments, software modules are hosted on one or more machines in more than one location.

A software module of a computer program may comprise an encoding and/or decoding algorithm. A software module comprising an encoding and/or decoding algorithm may be referred to as an encoder/decoder module, which is further described herein. An encoder/decoder module may generally map a string of symbols to another string of symbols. For example, an encoder may be used to map a first string comprising computer readable symbols (e.g., binary) to a second string of symbols representing sequences of molecules (e.g., nucleic acid or amino acid sequence). A decoder may be used to map, for example, a string of symbols representing sequences of molecules (e.g., nucleic acid or amino acid sequence) to a string comprising computer readable symbols (e.g., binary).

### Databases

In some embodiments, the platforms, systems, media, and methods disclosed herein include one or more databases, or use of the same. In view of the disclosure provided herein, those of skill in the art will recognize that many databases are suitable for storage and retrieval of information. In various embodiments, suitable databases include, by way of non-limiting examples, relational databases, non-relational databases, object oriented databases, object databases, entity-relationship model databases, associative databases, XML databases, document oriented databases, and graph databases. Further non-limiting examples include SQL, PostgreSQL, MySQL, Oracle, DB2, Sybase, and MongoDB. In some embodiments, a database is Internet-based. In further embodiments, a database is web-based. In still further embodiments, a database is cloud computing-based. In a particular embodiment, a database is a distributed database. In other embodiments, a database is based on one or more local computer storage devices. In some embodiments, the database is an organic database. In some instances, the database comprises one or more storage devices housing a plurality of molecules encoding information. The information may be stored or retrieved from the molecules using one or more instruments (e.g., robotic system, synthesizer, sequencer, amplification unit, etc.) described herein.

### Applications

In some embodiments, a computer program includes a web application. In light of the disclosure provided herein, those of skill in the art will recognize that a web application, in various embodiments, utilizes one or more software frameworks and one or more database systems. In some embodiments, a web application is created upon a software framework such as Microsoft® NET or Ruby on Rails (RoR). In some embodiments, a web application utilizes one or more database systems including, by way of non-limiting examples, relational, non-relational, object oriented, associative, XML, and document oriented database systems. In further embodiments, suitable relational database systems include, by way of non-limiting examples, Microsoft® SQL Server, mySQL™, and Oracle®. Those of skill in the art will also recognize that a web application, in various embodiments, is written in one or more versions of one or more languages. A web application may be written in one or more markup languages, presentation definition languages, client-side scripting languages, server-side coding languages, database query languages, or combinations thereof. In some embodiments, a web application is written to some extent in a markup language such as Hypertext Markup Language (HTML), Extensible Hypertext Markup Language (XHTML), or extensible Markup Language (XML). In some embodiments, a web application is written to some extent in a presentation definition language such as Cascading Style Sheets (CSS). In some embodiments, a web application is written to some extent in a client-side scripting language such as Asynchronous Javascript and XML (AJAX), Flash® ActionScript, JavaScript, or Silverlight®. In some embodiments, a web application is written to some extent in a server-side coding language such as Active Server Pages (ASP), ColdFusion®, Perl, Java™, JavaServer Pages (JSP), Hypertext Preprocessor (PHP), Python™, Ruby, Tcl, Smalltalk, WebDNA® or Groovy. In some embodiments, a web application is written to some extent in a database query language such as Structured Query Language (SQL). In some embodiments, a web application integrates enterprise server products such as IBM® Lotus Domino®. In some embodiments, a web application includes a media player element. In various further embodiments, a media player element utilizes one or more of many suitable multimedia technologies including, by way of non-limiting examples, Adobe® Flash®, HTML 5, Apple® QuickTime®, Microsoft® Silverlight®, Java™, and Unity®.

In some embodiments, a computer program includes a mobile application provided to a mobile computing device. In some embodiments, the mobile application is provided to a mobile computing device at the time it is manufactured. In other embodiments, the mobile application is provided to a mobile computing device via the computer network described herein.

In view of the disclosure provided herein, a mobile application is created by techniques known to those of skill in the art using hardware, languages, and development environments known to the art. Those of skill in the art will recognize that mobile applications are written in several languages. Suitable programming languages include, by way of non-limiting examples, C, C++, C#, Objective-C, Java™, JavaScript, Pascal, Object Pascal, Python™, Ruby, VB. NET, WML, and XHTML/HTML with or without CSS, or combinations thereof.

Suitable mobile application development environments are available from several sources. Commercially available development environments include, by way of non-limiting examples, AirplaySDK, alcheMo, Appcelerator®, Celsius, Bedrock, Flash Lite, .NET Compact Framework, Rhomobile, and WorkLight Mobile Platform. Other development environments are available without cost including, by way of non-limiting examples, Lazarus, MobiFlex, MoSync, and Phonegap. Also, mobile device manufacturers distribute software developer kits including, by way of non-limiting examples, iPhone and iPad (iOS) SDK, Android™ SDK, BlackBerry® SDK, BREW SDK, Palm® OS SDK, Symbian SDK, webOS SDK, and Windows® Mobile SDK.

Those of skill in the art will recognize that several commercial forums are available for distribution of mobile applications including, by way of non-limiting examples, Apple® App Store, Google® Play, Chrome WebStore, BlackBerry® App World, App Store for Palm devices, App Catalog for webOS, Windows® Marketplace for Mobile, Ovi Store for Nokia® devices, Samsung® Apps, and Nintendo® DSi Shop.

In some embodiments, a computer program includes a standalone application, which is a program that is run as an independent computer process, not an add-on to an existing process, e.g., not a plug-in. Those of skill in the art will recognize that standalone applications are often compiled. A compiler is a computer program(s) that transforms source code written in a programming language into binary object code such as assembly language or machine code. Suitable compiled programming languages include, by way of non-limiting examples, C, C++, Objective-C, COBOL, Delphi, Eiffel, Java™, Lisp, Python™, Visual Basic, and VB .NET, or combinations thereof. Compilation is often performed, at least in part, to create an executable program. In some embodiments, a computer program includes one or more executable complied applications.

In some embodiments, the computer program includes a web browser plug-in (e.g., extension, etc.). In computing, a plug-in is one or more software components that add specific functionality to a larger software application. Makers of software applications support plug-ins to enable third-party developers to create abilities which extend an application, to support easily adding new features, and to reduce the size of an application. When supported, plug-ins enable customizing the functionality of a software application. For example, plug-ins are commonly used in web browsers to play video, generate interactivity, scan for viruses, and display particular file types. Those of skill in the art will be familiar with several web browser plug-ins including, Adobe® Flash® Player, Microsoft® Silverlight®, and Apple® QuickTime®. In some embodiments, the toolbar comprises one or more web browser extensions, add-ins, or add-ons. In some embodiments, the toolbar comprises one or more explorer bars, tool bands, or desk bands.

In view of the disclosure provided herein, those of skill in the art will recognize that several plug-in frameworks are available that enable development of plug-ins in various programming languages, including, by way of non-limiting examples, C++, Delphi, Java™, PHP, Python™, and VB .NET, or combinations thereof.

Web browsers (also called Internet browsers) are software applications, designed for use with network-connected computing devices, for retrieving, presenting, and traversing information resources on the World Wide Web. Suitable web browsers include, by way of non-limiting examples, Microsoft® Internet Explorer®, Mozilla® Firefox®, Google® Chrome, Apple® Safari®, Opera Software® Opera®, and KDE Konqueror. In some embodiments, the web browser is a mobile web browser. Mobile web browsers (also called microbrowsers, mini-browsers, and wireless browsers) are designed for use on mobile computing devices including, by way of non-limiting examples, handheld computers, tablet computers, netbook computers, subnotebook computers, smartphones, music players, personal digital assistants (PDAs), and handheld video game systems. Suitable mobile web browsers include, by way of non-limiting examples, Google® Android® browser, RIM Blackberry® Browser, Apple® Safari®, Palm® Blazer, Palm® WebOS® Browser, Mozilla® Firefox® for mobile, Microsoft® Internet Explorer® Mobile, Amazon® Kindle® Basic Web, Nokia® Browser, Opera Software® Opera® Mobile, and Sony® PSP™ browser.

### Nucleic Acid Based Information Storage

Provided herein are devices, compositions, systems, and methods for nucleic acid-based information (data) storage. In some instances, the devices, compositions, platforms, systems, or methods provided herein are used for transfer of polynucleotides from one substrate to another for DNA data storage. A biomolecule such as a DNA molecule provides a suitable host for storage of information, such as digital information, in-part due to its stability over time and capacity for enhanced information coding, as opposed to traditional binary information coding. In addition, a biomolecule such as a DNA molecule can provide high volumetric storage density. In a first step, a digital sequence encoding an item of information (e.g., digital information in a binary code for processing by a computer) is received. The digital sequence can comprise a first plurality of symbols, such a binary, octal, decimal, or hexadecimal data. An encryption scheme is applied to convert the digital sequence from the first string of symbols to a second string of symbols. The second string of symbols can comprise an alternative representation to the first string of symbols. In some examples, the second string of symbols comprises a nucleic acid sequence.

Once an item of information is converted to a nucleic acid sequence, the nucleic acids can be synthesized. A surface material for nucleic acid extension, a design for loci for nucleic acid extension (aka, arrangement spots), and reagents for nucleic acid synthesis are selected. The surface of a structure is prepared for nucleic acid synthesis. De novo polynucleotide synthesis is then performed. The synthesized polynucleotides can be extracted, in whole or in part, using the systems, devices, methods, or platforms provided herein. The synthesized polynucleotides are stored in a structure and, in some cases, are available for subsequent release, in whole or in part. The synthesized polynucleotides may be stored in a structure suitable for long term storage (e.g., weeks, months, years, decades, etc.). A structure suitable for long term storage may be identifiable and/or capable of being catalogued, such as, for example, using a tag (e.g., barcode or RFID tag). The systems and methods provided herein may be used to transfer polynucleotides from a synthesis surface to a storage surface while providing spatial addressability and preserving spatial arrangement. Polynucleotides may be released or retrieved from storage to access the information. Once released, the polynucleotides, in whole or in part, can be sequenced, subject to decryption to convert nucleic sequence back to digital sequence. The digital sequence is then assembled to obtain an alignment encoding for the original item of information.

### Items of Information

Optionally, an early step of data storage process disclosed herein includes obtaining or receiving one or more items of information in the form of an initial code. In some instances, the items of information are encoded as a plurality of polynucleotides that have been extracted from a substrate, using systems, methods, platforms, or devices provided herein. Items of information (e.g., digital information) include, without limitation, text, audio, and visual information. Exemplary sources for items of information include, without limitation, books, periodicals, electronic databases, medical records, letters, forms, voice recordings, animal recordings, biological profiles, broadcasts, films, short videos, emails, bookkeeping phone logs, internet activity logs, drawings, paintings, prints, photographs, pixelated graphics, and software code. Exemplary biological profile sources for items of information include, without limitation, gene libraries, genomes, gene expression data, and protein activity data. Exemplary formats for items of information include, without limitation, .txt, .PDF, .doc, .docx, .ppt, .pptx, .xls, .xlsx, .rtf, .jpg, .gif, .psd, .bmp, .tiff, .png, and. mpeg. The amount of individual file sizes encoding for an item of information, or a plurality of files encoding for items of information, in digital format include, without limitation, up to 1024 bytes (equal to 1 KB), 1024 KB (equal to 1 MB), 1024 MB (equal to 1 GB), 1024 GB (equal to 1 TB), 1024 TB (equal to 1 PB), 1 exabyte, 1 zettabyte, 1 yottabyte, 1 xenottabyte or more. In some instances, an amount of digital information is at least 1 gigabyte (GB). In some instances, the amount of digital information is at least 1, 2, 3, 4, 5, 6, 7, 8, 9, 10, 20, 50, 100, 200, 300, 400, 500, 600, 700, 800, 900, 1000 or more than 1000 gigabytes. In some instances, the amount of digital information is at least 1 terabyte (TB). In some instances, the amount of digital information is at least 1, 2, 3, 4, 5, 6, 7, 8, 9, 10, 20, 50, 100, 200, 300, 400, 500, 600, 700, 800, 900, 1000 or more than 1000 terabytes. In some instances, the amount of digital information is at least 1 petabyte (PB). In some instances, the amount of digital information is at least 1, 2, 3, 4, 5, 6, 7, 8, 9, 10, 20, 50, 100, 200, 300, 400, 500, 600, 700, 800, 900, 1000 or more than 1000 petabytes. In some instances, the digital information does not contain genomic data acquired from an organism. Items of information in some instances are encoded. Non-limiting encoding method examples include 1 bit/base, 2 bit/base, 4 bit/base or other encoding method.

### De Novo Polynucleotide Synthesis

Provided herein are systems and methods for synthesis of libraries of polynucleotides on a substrate. In some instances, the library comprising a plurality of polynucleotides from the encoding scheme are synthesized. In some examples, the library comprising the plurality of polynucleotides from the encoding scheme encode a pool of the plurality of pools. In some examples, the library comprising the plurality of polynucleotides from the encoding scheme encode an index pool. In some instances, methods comprise use of electrochemical deprotection. In some instances, the substrate is a flexible substrate. In some instances, at least 10¹⁰, 10¹¹, 10¹², 10¹³, 10¹⁴, or 10¹⁵ bases are synthesized in one day. In some instances, at least 10×10⁸, 10×10⁹, 10×10¹⁰, 10×10¹¹, or 10×10¹² polynucleotides are synthesized in one day. In some cases, each polynucleotide synthesized comprises at least 20, 50, 100, 200, 300, 400 or 500 nucleobases. In some cases, these bases are synthesized with a total average error rate of less than about 1 in 100; 200; 300; 400; 500; 1000; 2000; 5000; 10000; 15000; 20000 bases. In some instances, these error rates are for at least 50%, 60%, 70%, 80%, 90%, 95%, 98%, 99%, 99.5%, or more of the polynucleotides synthesized. In some instances, these at least 90%, 95%, 98%, 99%, 99.5%, or more of the polynucleotides synthesized do not differ from a predetermined sequence for which they encode. In some instances, the error rate for synthesized polynucleotides on a substrate using the methods and systems described herein is less than about 1 in 200, less than about 1 in 1,000, less than about 1 in 2,000, less than about 1 in 3,000, or less than about 1 in 5,000. Individual types of error rates include mismatches, deletions, insertions, and/or substitutions for the polynucleotides synthesized on the substrate. The term “error rate” refers to a comparison of the collective amount of synthesized polynucleotide to an aggregate of predetermined polynucleotide sequences. In some instances, synthesized polynucleotides disclosed herein comprise a tether of 12 to 25 bases. In some instances, the tether comprises 10, 11, 12, 13, 14, 15, 16, 17, 17, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50 or more bases.

Described herein are methods, systems, devices, and compositions wherein chemical reactions used in polynucleotide synthesis are controlled using electrochemistry. Electrochemical reactions in some instances are controlled by any source of energy, such as light, heat, radiation, or electricity. For example, electrodes are used to control chemical reactions as all or a portion of discrete loci on a surface. Electrodes in some instances are charged by applying an electrical potential to the electrode to control one or more chemical steps in polynucleotide synthesis. In some instances, these electrodes are addressable. Any number of the chemical steps described herein is in some instances controlled with one or more electrodes. Electrochemical reactions may comprise oxidations, reductions, acid/base chemistry, or other reaction that is controlled by an electrode. In some instances, electrodes generate electrons or protons that are used as reagents for chemical transformations. Electrodes in some instances directly generate a reagent such as an acid. In some instances, an acid is a proton. Electrodes in some instances directly generate a reagent such as a base. Acids or bases are often used to cleave protecting groups, or influence the kinetics of various polynucleotide synthesis reactions, for example by adjusting the pH of a reaction solution. Electrochemically controlled polynucleotide synthesis reactions in some instances comprise redox-active metals or other redox-active organic materials. In some instances, metal or organic catalysts are employed with these electrochemical reactions. In some instances, acids are generated from oxidation of quinones.

Control of chemical reactions is not limited to the electrochemical generation of reagents; chemical reactivity may be influenced indirectly through biophysical changes to substrates or reagents through electric fields (or gradients) which are generated by electrodes. In some instances, substrates include but are not limited to polynucleotides. In some instances, electrical fields which repel or attract specific reagents or substrates towards or away from an electrode or surface are generated. Such fields in some instances are generated by application of an electrical potential to one or more electrodes. For example, negatively charged polynucleotides are repelled from negatively charged electrode surfaces. Such repulsions or attractions of polynucleotides or other reagents caused by local electric fields in some instances provides for movement of polynucleotides or other reagents in or out of region of the synthesis device or structure. In some instances, electrodes generate electric fields which repel polynucleotides away from a synthesis surface, structure, or device. In some instances, electrodes generate electric fields which attract polynucleotides towards a synthesis surface, structure, or device. In some instances, protons are repelled from a positively charged surface to limit contact of protons with substrates or portions thereof. In some instances, repulsion or attractive forces are used to allow or block entry of reagents or substrates to specific areas of the synthesis surface. In some instances, nucleoside monomers are prevented from contacting a polynucleotide chain by application of an electric field in the vicinity of one or both components. Such arrangements allow gating of specific reagents, which may obviate the need for protecting groups when the concentration or rate of contact between reagents and/or substrates is controlled. In some instances, unprotected nucleoside monomers are used for polynucleotide synthesis. Alternatively, application of the field in the vicinity of one or both components promote contact of nucleoside monomers with a polynucleotide chain. Additionally, application of electric fields to a substrate can alter the substrates reactivity or conformation. In an exemplary application, electric fields generated by electrodes are used to prevent polynucleotides at adjacent loci from interacting. In some instances, the substrate is a polynucleotide, optionally attached to a surface. Application of an electric field in some instances alters the three-dimensional structure of a polynucleotide. Such alterations comprise folding or unfolding of various structures, such as helices, hairpins, loops, or other 3-dimensional nucleic acid structure. Such alterations are useful for manipulating polynucleotides inside of wells, channels, or other structures. In some instances, electric fields are applied to a nucleic acid substrate to prevent secondary structures. In some instances, electric fields obviate the need for linkers or attachment to a solid support during polynucleotide synthesis.

A suitable method for polynucleotide synthesis on a substrate of this disclosure is a phosphoramidite-based synthesis of DNA. In some cases, a reagent for the phosphoramidite-based synthesis comprises any one of or a combination of a nucleoside phosphoramidite, an oxidizer, an activator, or a deblocker or the solvent comprises acetonitrile. In some instances, the phosphoramidite-based synthesis method comprises the controlled addition of a phosphoramidite building block, i.e., nucleoside phosphoramidite, to a growing polynucleotide chain in a coupling step that forms a phosphite triester linkage between the phosphoramidite building block and a nucleoside bound to the substrate. In some instances, the nucleoside phosphoramidite is provided to the substrate activated. In some instances, the nucleoside phosphoramidite is provided to the substrate with an activator. In some instances, nucleoside phosphoramidites are provided to the substrate in a 1.5, 2, 3, 4, 5, 6, 7, 8, 9, 10, 11, 12, 13, 14, 15, 16, 17, 17, 19, 20, 25, 30, 35, 40, 50, 60, 70, 80, 90, 100-fold excess or more over the substrate-bound nucleosides. In some instances, the addition of nucleoside phosphoramidite is performed in an anhydrous environment, for example, in anhydrous acetonitrile. Following addition and linkage of a nucleoside phosphoramidite in the coupling step, the substrate is optionally washed. In some instances, the coupling step is repeated one or more additional times, optionally with a wash step between nucleoside phosphoramidite additions to the substrate. In some instances, a polynucleotide synthesis method used herein comprises 1, 2, 3 or more sequential coupling steps. Prior to coupling, in many cases, the nucleoside bound to the substrate is de-protected by removal of a protecting group, where the protecting group functions to prevent polymerization. Protecting groups may comprise any chemical group that prevents extension of the polynucleotide chain. In some instances, the protecting group is cleaved (or removed) in the presence of an acid. In some instances, the protecting group is cleaved in the presence of a base. In some instances, the protecting group is removed with electromagnetic radiation such as light, heat, or other energy source. In some instances, the protecting group is removed through an oxidation or reduction reaction. In some instances, a protecting group comprises a triarylmethyl group. In some instances, a protecting group comprises an aryl ether. In some instances, a protecting comprises a disulfide. In some instances, a protecting group comprises an acid-labile silane. In some instances, a protecting group comprises an acetal. In some instances, a protecting group comprises a ketal. In some instances, a protecting group comprises an enol ether. In some instances, a protecting group comprises a methoxybenzyl group. In some instances, a protecting group comprises an azide. In some instances, a protecting group is 4,4′-dimethoxytrityl (DMT). In some instances, a protecting group is a tert-butyl carbonate. In some instances, a protecting group is a tert-butyl ester. In some instances, a protecting group comprises a base-labile group.

Following coupling, phosphoramidite polynucleotide synthesis methods optionally comprise a capping step. In a capping step, the growing polynucleotide is treated with a capping agent. A capping step generally serves to block unreacted substrate-bound 5′-OH groups after coupling from further chain elongation, preventing the formation of polynucleotides with internal base deletions. Further, phosphoramidites activated with 1H-tetrazole often react, to a small extent, with the O6 position of guanosine. Without being bound by theory, upon oxidation with I2/water, this side product, possibly via O6-N7 migration, undergoes depurination. The apurinic sites can end up being cleaved in the course of the final deprotection of the polynucleotide thus reducing the yield of the full-length product. The 06 modifications may be removed by treatment with the capping reagent prior to oxidation with I2/water. In some instances, inclusion of a capping step during polynucleotide synthesis decreases the error rate as compared to synthesis without capping. As an example, the capping step comprises treating the substrate-bound polynucleotide with a mixture of acetic anhydride and 1-methylimidazole. Following a capping step, the substrate is optionally washed.

Following addition of a nucleoside phosphoramidite, and optionally after capping and one or more wash steps, a substrate described herein comprises a bound growing nucleic acid that may be oxidized. The oxidation step comprises oxidizing the phosphite triester into a tetracoordinated phosphate triester, a protected precursor of the naturally occurring phosphate diester internucleoside linkage. In some instances, phosphite triesters are oxidized electrochemically. In some instances, oxidation of the growing polynucleotide is achieved by treatment with iodine and water, optionally in the presence of a weak base such as a pyridine, lutidine, or collidine. Oxidation is sometimes carried out under anhydrous conditions using tert-Butyl hydroperoxide or (1S)-(+)-(10-camphorsulfonyl)-oxaziridine (CSO). In some methods, a capping step is performed following oxidation. A second capping step allows for substrate drying, as residual water from oxidation that may persist can inhibit subsequent coupling. Following oxidation, the substrate and growing polynucleotide is optionally washed. In some instances, the step of oxidation is substituted with a sulfurization step to obtain polynucleotide phosphorothioates, wherein any capping steps can be performed after the sulfurization. Many reagents are capable of the efficient sulfur transfer, including, but not limited to, 3-(Dimethylaminomethylidene)amino)-3H-1,2,4-dithiazole-3-thione, DDTT, 3H-1,2-benzodithiol-3-one 1,1-dioxide, also known as Beaucage reagent, and N, N, N′N′-Tetraethylthiuram disulfide (TETD).

For a subsequent cycle of nucleoside incorporation to occur through coupling, a protected 5′ end (or 3′ end, if synthesis is conducted in a 5′ to 3′ direction) of the substrate bound growing polynucleotide is be removed so that the primary hydroxyl group can react with a next nucleoside phosphoramidite. In some instances, the protecting group is DMT and deblocking occurs with trichloroacetic acid in dichloromethane. In some instances, the protecting group is DMT and deblocking occurs with electrochemically generated protons. Conducting detritylation for an extended time or with stronger than recommended solutions of acids may lead to increased depurination of solid support-bound polynucleotide and thus reduces the yield of the desired full-length product. Methods and compositions described herein provide for controlled deblocking conditions limiting undesired depurination reactions. In some instances, the substrate bound polynucleotide is washed after deblocking. In some cases, efficient washing after deblocking contributes to synthesized polynucleotides having a low error rate.

Methods for the synthesis of polynucleotides on a substrate described herein may involve an iterating sequence of the following steps: application of a protected monomer to a surface of a substrate feature to link with either the surface, a linker or with a previously deprotected monomer; deprotection of the applied monomer so that it can react with a subsequently applied protected monomer; and application of another protected monomer for linking. One or more intermediate steps include oxidation and/or sulfurization. In some instances, one or more wash steps precede or follow one or all of the steps.

Methods for the synthesis of polynucleotides on a substrate described herein may comprise an oxidation step. For example, methods involve an iterating sequence of the following steps: application of a protected monomer to a surface of a substrate feature to link with either the surface, a linker or with a previously deprotected monomer; deprotection of the applied monomer so that it can react with a subsequently applied protected monomer; application of another protected monomer for linking, and oxidation and/or sulfurization. In some instances, one or more wash steps precede or follow one or all of the steps.

Methods for the synthesis of polynucleotides on a substrate described herein may further comprise an iterating sequence of the following steps: application of a protected monomer to a surface of a substrate feature to link with either the surface, a linker or with a previously deprotected monomer; deprotection of the applied monomer so that it can react with a subsequently applied protected monomer; and oxidation and/or sulfurization. In some instances, one or more wash steps precede or follow one or all of the steps.

Methods for the synthesis of polynucleotides on a substrate described herein may further comprise an iterating sequence of the following steps: application of a protected monomer to a surface of a substrate feature to link with either the surface, a linker or with a previously deprotected monomer; and oxidation and/or sulfurization. In some instances, one or more wash steps precede or follow one or all of the steps.

Methods for the synthesis of polynucleotides on a substrate described herein may further comprise an iterating sequence of the following steps: application of a protected monomer to a surface of a substrate feature to link with either the surface, a linker or with a previously deprotected monomer; deprotection of the applied monomer so that it can react with a subsequently applied protected monomer; and oxidation and/or sulfurization. In some instances, one or more wash steps precede or follow one or all of the steps.

In some instances, polynucleotides are synthesized with photolabile protecting groups, where the hydroxyl groups generated on the surface are blocked by photolabile-protecting groups. When the surface is exposed to UV light, such as through a photolithographic mask, a pattern of free hydroxyl groups on the surface may be generated. These hydroxyl groups can react with photoprotected nucleoside phosphoramidites, according to phosphoramidite chemistry. A second photolithographic mask can be applied, and the surface can be exposed to UV light to generate second pattern of hydroxyl groups, followed by coupling with 5′-photoprotected nucleoside phosphoramidite. Likewise, patterns can be generated, and oligomer chains can be extended. Without being bound by theory, the lability of a photocleavable group depends on the wavelength and polarity of a solvent employed and the rate of photocleavage may be affected by the duration of exposure and the intensity of light. This method can leverage a number of factors such as accuracy in alignment of the masks, efficiency of removal of photo-protecting groups, and the yields of the phosphoramidite coupling step. Further, unintended leakage of light into neighboring sites can be minimized. The density of synthesized oligomer per spot can be monitored by adjusting loading of the leader nucleoside on the surface of synthesis.

The surface of a substrate described herein that provides support for polynucleotide synthesis may be chemically modified to allow for the synthesized polynucleotide chain to be cleaved from the surface. In some instances, the polynucleotide chain is cleaved at the same time as the polynucleotide is deprotected. In some cases, the polynucleotide chain is cleaved after the polynucleotide is deprotected. In an exemplary scheme, a trialkoxysilyl amine such as (CH₃CH₂O)₃Si—(CH₂)₂—NH₂ is reacted with surface SiOH groups of a substrate, followed by reaction with succinic anhydride with the amine to create an amide linkage and a free OH on which the nucleic acid chain growth is supported. Cleavage includes gas cleavage with ammonia or methylamine. In some instances, cleavage includes linker cleavage with electrically generated reagents such as acids or bases. In some instances, once released from the surface, polynucleotides are assembled into larger polynucleotides that are sequenced and decoded to extract stored information.

The surfaces described herein can be reused after polynucleotide cleavage to support additional cycles of polynucleotide synthesis. For example, the linker can be reused without additional treatment/chemical modifications. In some instances, a linker is non-covalently bound to a substrate surface or a polynucleotide. In some embodiments, the linker remains attached to the polynucleotide after cleavage from the surface. Linkers in some embodiments comprise reversible covalent bonds such as esters, amides, ketals, beta substituted ketones, heterocycles, or other group that is capable of being reversibly cleaved. Such reversible cleavage reactions are in some instances controlled through the addition or removal of reagents, or by electrochemical processes controlled by electrodes. Optionally, chemical linkers or surface-bound chemical groups are regenerated after a number of cycles, to restore reactivity and remove unwanted side product formation on such linkers or surface-bound chemical groups.

Alternatively, the polymer synthesis can be enzymatic DNA synthesis. In some cases, the enzymatic DNA synthesis uses water as a solvent and the reagent is an enzyme terminal deoxynucleotidyl transferase (TdT) or a deblocker. In some cases, enzymatic synthesis of DNA uses a template-independent DNA polymerase, terminal deoxynucleotidyl transferase (TdT), which is a protein that evolved to rapidly catalyze the linkage of naturally occurring dNTPs. TdT adds nucleotides indiscriminately, so it is stopped from continuing unregulated synthesis by various techniques such a tethering the TDT, creating variant enzymes, and using nucleotides that include reversible terminators to prevent chain elongation. TdT activity is maximized at approximately 37° C. and performs enzymatic reactions in an aqueous environment.

### Sequencing

Polynucleotides are extracted and/or amplified from surfaces where they are synthesized or stored. After extraction and/or amplification of polynucleotides from the surface of a structure, suitable sequencing technology may be employed to sequence the polynucleotides. In some cases, the DNA sequence is read on the substrate or within a feature of a structure. In some cases, the polynucleotides stored on the substrate are extracted is optionally assembled into longer polynucleotides and then sequenced.

Polynucleotides synthesized and stored on the structures described herein encode data that can be interpreted by reading the sequence of the synthesized polynucleotides and converting the sequence into binary code readable by a computer. In some cases, the sequences require assembly, and the assembly step may need to be at the nucleic acid sequence stage or at the digital sequence stage.

Provided herein are detection systems comprising a device capable of sequencing stored polynucleotides, either directly on the synthesis structure and/or after removal from the main structure (e.g., synthesis structure, storage structure, etc.). In cases where the synthesis structure is a reel-to-reel tape of flexible material, the detection system comprises a device for holding and advancing the structure through a detection location and a detector disposed proximate the detection location for detecting a signal originated from a section of the tape when the section is at the detection location. In some instances, the signal is indicative of a presence of a polynucleotide. In some instances, the signal is indicative of a sequence of a polynucleotide (e.g., a fluorescent signal). In some instances, information encoded within polynucleotides on a continuous tape is read by a computer as the tape is conveyed continuously through a detector operably connected to the computer. In some instances, a detection system comprises a computer system comprising a polynucleotide sequencing device, a database for storage and retrieval of data relating to polynucleotide sequence, software for converting DNA code of a polynucleotide sequence to binary code, a computer for reading the binary code, or any combination thereof.

Provided herein are sequencing systems that can be integrated into the devices described herein. Various methods of sequencing are well known in the art and comprise “base calling” wherein the identity of a base in the target polynucleotide is identified. In some instances, polynucleotides synthesized using the methods, devices, compositions, and systems described herein are sequenced after cleavage from the synthesis surface. In some instances, sequencing occurs during or simultaneously with polynucleotide synthesis, wherein base calling occurs immediately after or before extension of a nucleoside monomer into the growing polynucleotide chain. Methods for base calling include measurement of electrical currents/voltages generated by polymerase-catalyzed addition of bases to a template strand. In some instances, synthesis surfaces comprise enzymes, such as polymerases. In some instances, such enzymes are tethered to electrodes or to the synthesis surface. In some instances, enzymes comprise terminal deoxynucleotidyl transferases, or variants thereof.

The present disclosure is further described by the following non-limiting items.
Item 1. A method of transferring information, comprising:
(a) storing the information in a plurality of biomolecules, wherein the plurality of molecules reside at one or more first loci of a first surface;
(b) providing a second surface comprising one or more second loci, wherein the second one or more loci comprise one or more droplets;
(c) contacting the plurality of biomolecules residing on at least one locus of the first surface with at least one droplet of the second surface; and
(d) transferring the plurality of biomolecules at the at least one locus of the first substrate to the at least one droplet of the second surface.
Item 2. The method of item 1, wherein the one or more first loci correspond at least partially to locations of the one or more second loci.
Item 3. The method of item 1 or 2, wherein the one or more first loci correspond to locations of the one or more second loci.
Item 4. The method of any one of items 1-3, wherein the one or more first loci, the one or more second loci, or both comprise:
(i) an inner region comprising a first functionalization agent; and
(ii) an outer region comprising a second functionalization agent.
Item 5. The method of item 4, wherein the first functionalization agent and the second functionalization agent are different.
Item 6. The method of item 4 or 5, wherein the inner region comprises a hydrophilic region.
Item 7. The method of any one of items 4-6, wherein the outer region comprises a hydrophobic region surrounding the inner region.
Item 8. The method of any one of items 1-7, wherein the one or more first loci, the one or more second loci, or both comprise a pitch distance of about 0.1 μm to about 10 μm.
Item 9. The method of any one of items 1-8, wherein the one or more first loci, the one or more second loci, or both comprise a pitch distance of about 1 μm.
Item 10. The method of any one of items 1-9, wherein (b) comprises forming the one or more droplets on the second surface by cooling the second surface in a humid environment.
Item 11. The method of any one of items 1-10, wherein the first surface, the second surface, or both is a surface of a substrate for biomolecule synthesis, biomolecule storage, or both.
Item 12. The method of any one of items 1-11, wherein the substrate comprising the first surface is a complementary metal-oxide semiconductor (CMOS) chip.
Item 13. The method of any one of items 1-11, wherein the substrate comprising the second surface is a glass chip.
Item 14. The method of any one of items 1-13, wherein one or more first loci, the one or more second loci, or both are addressable.
Item 15. The method of any one of items 1-14, wherein (c) comprises aligning the first surface with the second surface.
Item 16. The method of any one of items 1-15, wherein (d) comprises preserving spatial arrangement or information thereof of the plurality of biomolecules.
Item 17. The method of any one of items 1-16, wherein (d) comprises cleaving the plurality of biomolecules from the first surface.
Item 18. The method of any one of items 1-17, wherein (d) comprises attaching the plurality of biomolecules to the second surface.
Item 19. The method of item 18, wherein attaching the plurality of biomolecules to the second surface comprises conjugating the plurality of biomolecules to the second surface.
Item 20. The method of item 19, wherein conjugating the plurality of biomolecules to the second surface comprise conjugating using click chemistry.
Item 21. The method of item 20, wherein the click chemistry comprises an azide-alkyne click conjugation.
Item 22. The method of any one of items 1-21, further comprising functionalizing the inner region of the second surface, the plurality of biomolecules, or both prior to (c).
Item 23. The method of item 22, wherein the inner region of the second surface, the plurality of biomolecules, or both are functionalized with a clickable moiety.
Item 24. The method of item 22, wherein the inner region of the second surface or the plurality of biomolecules are functionalized with a thiol, an imidazole, an amine, an alkyne, a diene, or a biotin.
Item 25. The method of item 24, wherein the inner region of the second surface or the plurality of biomolecules are functionalized with a maleimide, a haloacetamide, an aldehyde, an isothiocyanate, an isocyanate, a vinyl sulphone, an azide, or a tetrazine, or a streptavidin.
Item 26. A system for transferring information, comprising:
(a) at least one processing unit;
(b) a memory in communication with the at least one processing unit;
(c) an organic storage in communication with the at least one processing unit and the memory, wherein the organic storage comprises:
   (i) at least one active surface comprising a plurality of molecules encoding information, wherein the plurality of molecules reside on one or more first loci; and
   (ii) at least one inactive surface comprising one or more droplets, wherein the one or more droplets reside on one or more second loci; and
(d) instructions stored in the memory and executed on the one or more processing units that cause the system to transfer the information in the organic storage through one or more operations, wherein the one or more operations comprise:
   (i) contacting the plurality of biomolecules at least one locus of the at least one active surface with at least one droplet of the at least one inactive surface; and
   (ii) transferring the plurality of biomolecules at the at least one locus to the at least one droplet of the at least one inactive surface.
Item 27. The system of item 26, wherein the one or more first loci correspond at least partially to locations of the one or more second loci.
Item 28. The system of item 26 or 27, wherein the one or more first loci correspond to locations of the one or more second loci.
Item 29. The system of any one of items 26-28, wherein the one or more first loci, the one or more second loci, or both comprise:
(i) an inner region comprising a first functionalization agent; and
(ii) an outer region comprising a second functionalization agent.
Item 30. The system of item 29, wherein the first functionalization agent and the second functionalization agent are different.
Item 31. The system of item 29 or 30, wherein the inner region comprises a hydrophilic region.
Item 32. The system of any one of items 29-31, wherein the outer region comprises a hydrophobic region surrounding the inner region.
Item 33. The system of any one of items 26-32, wherein the one or more first loci, the one or more second loci, or both comprise a pitch distance of about 0.1 μm to about 10 μm.
Item 34. The system of any one of items 26-33, wherein the one or more first loci, the one or more second loci, or both comprise a pitch distance of about 1 μm.
Item 35. The system of any one of items 26-34, wherein the active surface, the inactive surface or both is a surface of a substrate for biomolecule synthesis, biomolecule storage, or both.
Item 36. The system of 35, wherein the substrate comprising the active surface is a complementary metal-oxide semiconductor (CMOS) chip.
Item 37. The system of 35, wherein the substrate comprising the inactive surface is a glass chip.
Item 38. The system of any one of items 26-37, wherein the one or more first loci, the one or more second loci, or both are addressable.
Item 39. The system of any one of items 26-38, wherein the one or more first loci, the one or more second loci, or both are addressable by electrode.
Item 40. The system of any one of items 26-39, further comprising a deposition chamber, wherein the deposition chamber deposits one or more droplets on to at least one inactive surface.
Item 41. The system of any one of items 26-40, further comprising a synthesizer unit for generating the plurality of molecules on the at least one locus of the at least one active surface.
Item 42. The system of any one of items 26-41, further comprising a robotic system for aligning the at least one active surface with the at least one inactive surface in (d)(i).
Item 43. The system of any one of items 26-42, wherein (d)(ii) comprises cleaving the plurality of biomolecules from the at least one active surface.
Item 44. The system of any one of items 26-43, wherein (d)(ii) further comprises attaching the plurality of biomolecules to the inactive surface.
Item 45. The system of any one of items 26-44, wherein attaching the plurality of biomolecules to the inactive surface comprises conjugating the plurality of biomolecules to the inactive surface.
Item 46. The system of item 45, wherein conjugating the plurality of biomolecules to the inactive surface comprise conjugating using click chemistry.
Item 47. The system of item 46, wherein the click chemistry comprises an azide-alkyne click conjugation.

### EXAMPLES

The following illustrative examples are representative of embodiments of the software applications, systems, and methods described herein and are not meant to be limiting in any way.

### Example 1—Information Transfer on a Surface

Digital information is encoded as sequences of a plurality of polynucleotides. The plurality of polynucleotides are synthesized on inner regions of loci on a substrate, as exemplary illustrated in FIG. 1B. The polynucleotides are synthesized with a standard phosphoramidite-based chemical oligomer synthesis protocol for a single substrate generally including repetitive addition of bases with the cyclic operation of deblocking, coupling, capping, and oxidation for every base to be added with intermittent washing steps to prevent cross-contamination. The terminal base is functionalized with an alkyne as shown in FIG. 2.

A surface is prepared with a plurality of loci with inner regions and an outer barrier, as shown in FIG. 1A. The inner regions are functionalized with a hydrophilic moiety, while the outer barrier is functionalized with a hydrophobic moiety. The inner regions of the surface are functionalized with an azide. The surface is placed in a deposition chamber comprising a humid environment, and droplets are formed at each locus on the surface. The droplets are contained by the hydrophobic outer barrier and reside on the inner region of each locus on the surface.

The information is transferred by transferring the polynucleotides encoding the information from one surface to another following the schematic generally illustrated in FIGS. 1A-1B that maintains spatial addressability. The first surface comprising polynucleotides and the second surface comprising droplets are aligned, and the polynucleotides and the droplets are contacted. The polynucleotides are conjugated to the second surface by azide-alkyne click chemistry following the general schematic provided in FIG. 2. The polynucleotides are then cleaved from the first surface to transfer the polynucleotides while preserving the spatial arrangement of information. Once the polynucleotides are cleaved from the first surface, the first surface is reused for polynucleotide synthesis.

While preferred embodiments of the present subject matter have been shown and described herein, it will be obvious to those skilled in the art that such embodiments are provided by way of example only. Numerous variations, changes, and substitutions will now occur to those skilled in the art without departing from the present subject matter. It should be understood that various alternatives to the embodiments of the present subject matter described herein may be employed in practicing the present subject matter.

1. A method of transferring information, comprising:
storing the information in a plurality of biomolecules, wherein the plurality of biomolecules reside at one or more first loci of a first surface;
providing a second surface comprising one or more second loci, wherein the one or more second loci comprise one or more droplets;
contacting the plurality of biomolecules residing on at least one locus of the first surface with at least one droplet of the second surface; and
transferring the plurality of biomolecules at the at least one locus of the first surface to the at least one droplet of the second surface.

2. The method of claim 1, wherein the one or more first loci, the one or more second loci, or both, comprise:
an inner region comprising a first functionalization agent; and
an outer region comprising a second functionalization agent.

3. The method of claim 2, wherein the inner region comprises a hydrophilic region and the outer region comprises a hydrophobic region.

4. The method of claim 1, wherein the one or more first loci, the one or more second loci, or both, comprise a pitch distance of about 0.1 μm to about 10 μm.

5. The method of claim 1, wherein the one or more droplets on the second surface are formed by cooling the second surface in a humid environment.

6. The method of claim 1, wherein:
contacting the plurality of biomolecules residing on at least one locus of the first surface with at least one droplet of the second surface comprises aligning the first surface with the second surface; and
transferring the plurality of biomolecules at the at least one locus of the first surface to the at least one droplet of the second surface comprises preserving spatial arrangement or information thereof of the plurality of biomolecules.

7. The method of claim 1, wherein transferring the plurality of biomolecules at the at least one locus of the first surface to the at least one droplet of the second surface comprises:
conjugating the plurality of biomolecules to the second surface; and
cleaving the plurality of biomolecules from the first surface.

8. The method of claim 2, further comprising:
prior to contacting the plurality of biomolecules residing on at least one locus of the first surface with at least one droplet of the second surface, functionalizing the inner region of the second surface, the plurality of biomolecules, or both.

9. The method of claim 8, wherein the inner region of the second surface, the plurality of biomolecules, or both are functionalized with a clickable moiety.

10. The method of claim 8, wherein the inner region of the second surface or the plurality of biomolecules are functionalized with a thiol, an imidazole, an amine, an alkyne, a diene, or a biotin.

11. A system for transferring information, comprising:
at least one processing unit;
a memory unit in communication with the at least one processing unit;
an organic storage unit in communication with the at least one processing unit and the memory unit, wherein the organic storage unit comprises:
at least one active surface comprising a plurality of biomolecules encoding information, wherein the plurality of biomolecules reside on one or more first loci; and
at least one inactive surface comprising one or more droplets, wherein the one or more droplets reside on one or more second loci; and
instructions stored in the memory unit and executed on the at least one processing unit that cause the system to transfer the information in the organic storage unit through one or more operations, wherein the one or more operations comprise:
contacting the plurality of biomolecules at least one locus of the at least one active surface with at least one droplet of the at least one inactive surface; and
transferring the plurality of biomolecules at the at least one locus to the at least one droplet of the at least one inactive surface.

12. The system of claim 11, wherein transferring the plurality of biomolecules at the at least one locus to the at least one droplet of the at least one inactive surface comprises:
conjugating the plurality of biomolecules to the inactive surface; and
cleaving the plurality of biomolecules from the at least one active surface.

13. The system of claim 11, wherein transferring the plurality of biomolecules at the at least one locus to the at least one droplet of the at least one inactive surface comprises preserving spatial arrangement or information thereof of the plurality of biomolecules.

14. The system of claim 11, wherein the one or more first loci, the one or more second loci, or both, are addressable by electrode.

15. The system of claim 11, further comprising a deposition chamber, wherein the deposition chamber deposits the one or more droplets on the at least one inactive surface.

16. The system of claim 11, further comprising a synthesizer unit, wherein the synthesizer unit generates the plurality of biomolecules on the at least one active surface.

17. The system of claim 11, further comprising a robotic system configured to align the at least one active surface with the at least one inactive surface.

18. The system of claim 11, wherein the one or more first loci, the one or more second loci, or both comprise:
an inner region comprising a first functionalization agent and a hydrophilic region; and
an outer region comprising a second functionalization agent and a hydrophobic region.

19. The system of claim 18, wherein the inner region comprises a hydrophilic region and the outer region comprises a hydrophobic region.

20. The system of claim 11, wherein the one or more first loci, the one or more second loci, or both comprise a pitch distance of about 0.1 μm to about 10 μm.
